(19) United States
(12) Patent Application Publication
(10) Pub. No.: US 2023/0361014 A1
(43) Pub. Date: Nov. 9, 2023

(54) ELECTRONIC PACKAGE

(71) Applicant: Advanced Semiconductor Engineering, Inc., Kaohsiung (TW)

(72) Inventor: Cheng-Lin HO, Kaohsiung (TW)

(73) Assignee: Advanced Semiconductor Engineering, Inc., Kaohsiung (TW)

(21) Appl. No.: 17/738,768

(22) Filed: May 6, 2022

(51) Int. Cl. H01L 23/498; H01L 23/31; H01L 23/528

(52) U.S. Cl. CPC H01L 23/49822; H01L 23/3107; H01L 23/528; H01L 23/49827; H01L 23/49816; H01L 2224/73204; H01L 24/73

(57) ABSTRACT

An electronic package includes an electronic structure, a first circuit pattern structure, a plurality of first solders and an encapsulant. The electronic structure includes an electronic device, and has a top surface and a bottom surface opposite to the top surface. The first circuit pattern structure is disposed over the top surface of the electronic structure. The first solders are disposed on the bottom surface of the electronic structure. The encapsulant encapsulates the electronic structure. At least a portion of the encapsulant is disposed between at least two of the plurality of first solders.

### BACKGROUND

### 1. Field of the Disclosure

The present disclosure relates to an electronic package, and to an electronic package including a circuit pattern structure.

### 2. Description of the Related Art

Along with the rapid development in electronics industry and the progress of semiconductor processing technologies, semiconductor chips are integrated with an increasing number of electronic components to achieve better electrical performance and more functions. Accordingly, the semiconductor chips are provided with more input/output (I/O) connections. To manufacture semiconductor packages including semiconductor chips with an increased number of I/O connections, circuit layers of semiconductor substrates used for carrying the semiconductor chips may correspondingly increase. Thus, thickness of the semiconductor substrate may correspondingly increase, and yield of the semiconductor substrate may decrease.

### SUMMARY

In some embodiments, an electronic package includes an electronic structure, a first circuit pattern structure, a plurality of first solders and an encapsulant. The electronic structure includes an electronic device, and has a top surface and a bottom surface opposite to the top surface. The first circuit pattern structure is disposed over the top surface of the electronic structure. The first solders are disposed on the bottom surface of the electronic structure. The encapsulant encapsulates the electronic structure. At least a portion of the encapsulant is disposed between at least two of the plurality of first solders.

In some embodiments, an electronic package includes an electronic structure and a second circuit pattern structure. The electronic structure includes a first circuit pattern structure. The second circuit pattern structure is disposed over the electronic structure. A gap is between the first circuit pattern structure and the second circuit pattern structure. The gap includes a first region and a second region. The first region is closer to a lateral surface of the second circuit pattern structure than the second region is. A height of the first region is less than a height of the second region.

In some embodiments, an electronic package includes a first circuit pattern structure, an electronic device, an upper electronic element and a second circuit pattern structure. The electronic device is disposed adjacent to the first circuit pattern structure. The upper electronic element disposed above the electronic device. The second circuit pattern structure is disposed between the electronic device and the upper electronic element. A first communication path is from the electronic device to the upper electronic element through the first circuit pattern structure. A second communication path is from the electronic device to the upper electronic element through the second circuit pattern structure without passing through the first circuit pattern structure.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic package according to some embodiments of the present disclosure.

FIG. 1A illustrates an enlarged view of an area “A” of FIG. 1.

FIG. 1B illustrates an enlarged view of an area of an electronic package according to some embodiments of the present disclosure.

FIG. 1C illustrates an enlarged view of an area of an electronic package according to some embodiments of the present disclosure.

FIG. 1D illustrates a cross-sectional view of an electronic package according to some embodiments of the present disclosure.

FIG. 2 illustrates a cross-sectional view of an electronic package according to some embodiments of the present disclosure.

FIG. 3 illustrates a cross-sectional view of an electronic package according to some embodiments of the present disclosure.

FIG. 4 illustrates a cross-sectional view of an electronic package according to some embodiments of the present disclosure.

FIG. 5 illustrates a cross-sectional view of an electronic package according to some embodiments of the present disclosure.

FIG. 5A illustrates an enlarged view of an area “B” of FIG. 5.

FIG. 5B illustrates a cross-sectional view of an electronic package according to some embodiments of the present disclosure.

FIG. 6 illustrates a cross-sectional view of an electronic package according to some embodiments of the present disclosure.

FIG. 7 illustrates a cross-sectional view of an electronic package according to some embodiments of the present disclosure.

FIG. 7A illustrates an enlarged view of an area “C” of FIG. 7.

FIG. 8 illustrates a cross-sectional view of an electronic package according to some embodiments of the present disclosure.

FIG. 9 illustrates one or more stages of an example of a method for manufacturing an electronic package according to some embodiments of the present disclosure.

FIG. 10 illustrates one or more stages of an example of a method for manufacturing an electronic package according to some embodiments of the present disclosure.

FIG. 11 illustrates one or more stages of an example of a method for manufacturing an electronic package according to some embodiments of the present disclosure.

FIG. 12 illustrates one or more stages of an example of a method for manufacturing an electronic package according to some embodiments of the present disclosure.

FIG. 13 illustrates one or more stages of an example of a method for manufacturing an electronic package according to some embodiments of the present disclosure.

FIG. 14 illustrates one or more stages of an example of a method for manufacturing an electronic package according to some embodiments of the present disclosure.

FIG. 15 illustrates one or more stages of an example of a method for manufacturing an electronic package according to some embodiments of the present disclosure.

FIG. 16 illustrates one or more stages of an example of a method for manufacturing an electronic package according to some embodiments of the present disclosure.

FIG. 17 illustrates one or more stages of an example of a method for manufacturing an electronic package according to some embodiments of the present disclosure.

FIG. 18 illustrates one or more stages of an example of a method for manufacturing an electronic package according to some embodiments of the present disclosure.

FIG. 19 illustrates one or more stages of an example of a method for manufacturing an electronic package according to some embodiments of the present disclosure.

FIG. 20 illustrates one or more stages of an example of a method for manufacturing an electronic package according to some embodiments of the present disclosure.

FIG. 21 illustrates one or more stages of an example of a method for manufacturing an electronic package according to some embodiments of the present disclosure.

FIG. 22 illustrates one or more stages of an example of a method for manufacturing an electronic package according to some embodiments of the present disclosure.

FIG. 23 illustrates one or more stages of an example of a method for manufacturing an electronic package according to some embodiments of the present disclosure.

FIG. 24 illustrates one or more stages of an example of a method for manufacturing an electronic package according to some embodiments of the present disclosure.

FIG. 25 illustrates one or more stages of an example of a method for manufacturing an electronic package according to some embodiments of the present disclosure.

FIG. 26 illustrates one or more stages of an example of a method for manufacturing an electronic package according to some embodiments of the present disclosure.

FIG. 27 illustrates one or more stages of an example of a method for manufacturing an electronic package according to some embodiments of the present disclosure.

FIG. 28 illustrates one or more stages of an example of a method for manufacturing an electronic package according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

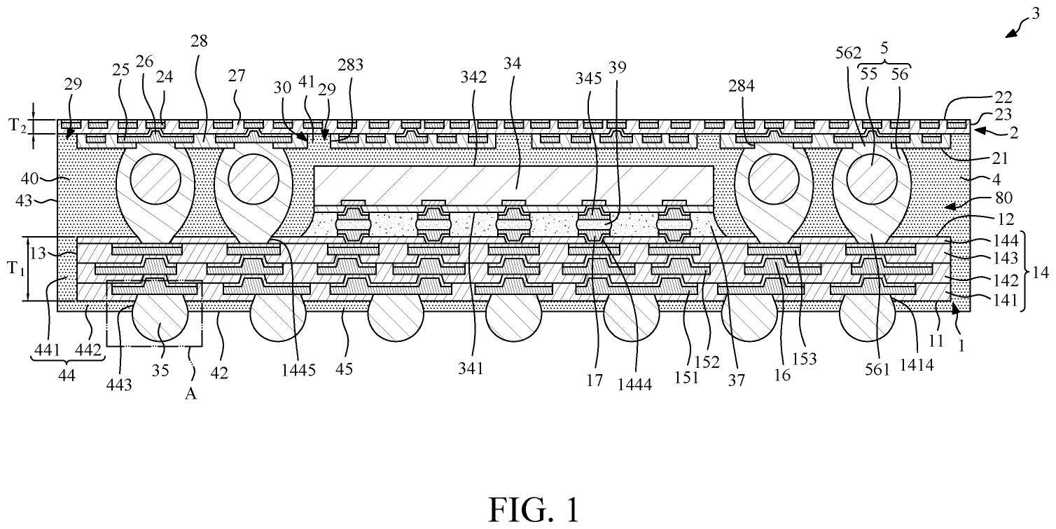

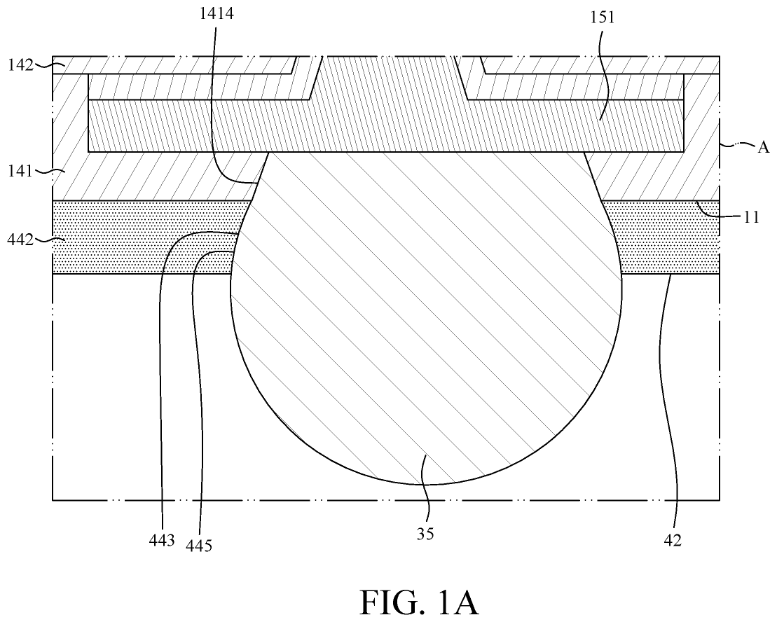

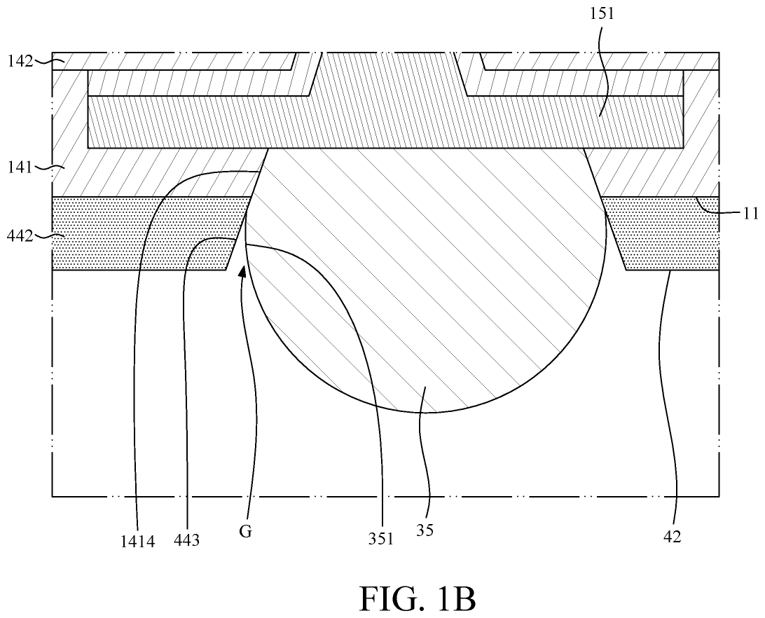

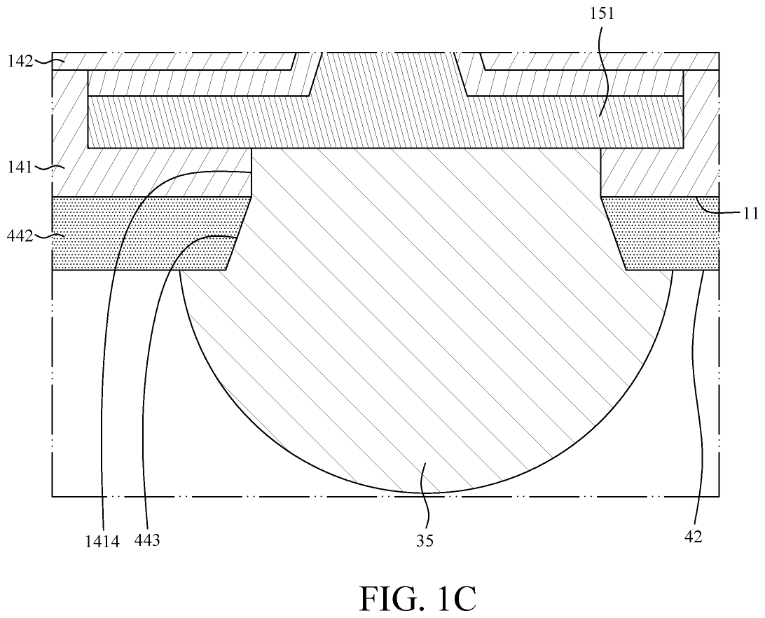

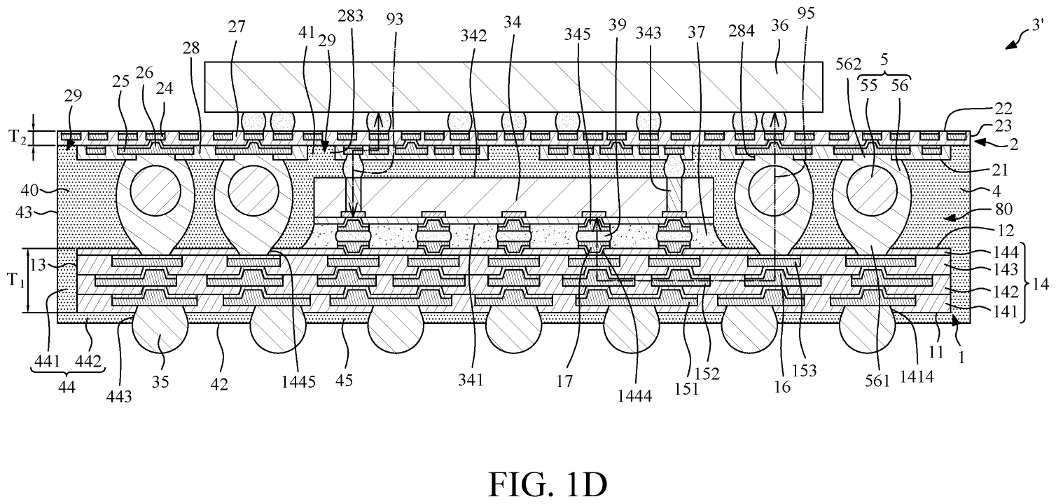

FIG. 1 illustrates a cross-sectional view of an electronic package 3 according to some embodiments of the present disclosure. The electronic package 3 may include an electronic structure 80, a second circuit pattern structure 2, at least one vertical conductive structure 5, an encapsulant 4 and at least one external connector 35. In some embodiments, the electronic package 3 may be an electronic package.

The electronic structure 80 may include a first circuit pattern structure 1, an electronic device 34 and an underfill 37. The first circuit pattern structure 1 may be a redistribution structure or an embedded trace substrate (ETS), and may have a first surface 11 (e.g., a bottom surface), a second surface 12 (e.g., a top surface) opposite to the first surface 11, and a lateral surface 13 extending between the first surface 11 and the second surface 12. The first surface 11 (e.g., bottom surface) of the first circuit pattern structure 1 may be a bottom surface of the electronic structure 80. The first circuit pattern structure 1 may include a dielectric structure 14, a plurality of circuit layers 151, 152, 153, a plurality of inner vias 16 and a plurality of bonding pads 17. The dielectric structure 14 may include a plurality of dielectric layers (including, for example, a first dielectric layer 141, a second dielectric layer 142, a third dielectric layer 143 and a fourth dielectric layer 144). The second dielectric layer 142, the third dielectric layer 143 and the fourth dielectric layer 144 may be disposed on a top surface of the first dielectric layer 141 and stacked on one another. The first dielectric layer 141, the second dielectric layer 142, the third dielectric layer 143 and the fourth dielectric layer 144 may be made of a cured photoimageable dielectric (PID) material such as epoxy or polyimide (PI) including photoinitiators. In some embodiments, the fourth dielectric layer 144 and the first dielectric layer 141 may include solder mask.

The circuit layers 151, 152, 153 may include a first circuit layer 151, a second circuit layer 152 and a third circuit layer 153, and may be embedded in the dielectric structure 14. Each of the circuit layers 151, 152, 153 may be a redistribution layer (RDL) or a conductive layer. In some embodiments, each of the circuit layers 151, 152, 153 may include a metallic layer (e.g. copper) disposed on a seed layer (e.g., titanium copper). In some embodiments, each of the circuit layers 151, 152, 153 may include at least one trace and at least one pad. The inner vias 16 may electrically connect at least one of the circuit layers 151, 152, 153 or two adjacent circuit layers 151, 152, 153. In some embodiments, the inner vias 16 may taper upward. That is, a width of each of the inner vias 16 may gradually decrease toward the fourth dielectric layer 144. In addition, the first dielectric layer 141 may define a plurality of openings 1414 extending through the first dielectric layer 141 to expose portions of the bottommost circuit layer (e.g., the first circuit layer 151). The topmost dielectric layer (e.g., the fourth dielectric layer 144) may cover the topmost circuit layer (e.g., the third circuit layer 153), and may define a plurality of openings (including, for example, openings 1444 and openings 1445) to expose portions of the topmost circuit layer (e.g., the third circuit layer 153).

The bonding pads 17 may be disposed in the openings 1444 of the topmost dielectric layer (e.g., the fourth dielectric layer 144) and on the exposed portions of the topmost circuit layer (e.g., the third circuit layer 153).

The first circuit pattern structure 1 may be also referred to as “a stacked structure” or “a low-density electronic structure”, “a low-density redistribution structure” or “a low-density stacked structure.” In addition, the first circuit pattern structure 1 may be also referred to as “a second circuit pattern structure.” Each of the circuit layers (including the first circuit layer 151, the second circuit layer 152 and the third circuit layer 153) of the first circuit pattern structure 1 may be also referred to as “a low-density redistribution layer” or “a low-density circuit layer.” The first circuit pattern structure 1 has a thickness T₁.

In some embodiments, the electronic package 3 may include a plurality of vertical conductive structures 5 spaced apart from each other. In some embodiments, the vertical conductive structure 5 may be disposed around the electronic device 34. The vertical conductive structure 5 may include a core portion 55 and a reflowable material 56 (e.g., second solder) enclosing the core portion 55. The core portion 55 may be disposed in the reflowable material 56 (e.g., second solder), and may be closer to the second circuit pattern structure 2 than to the first circuit pattern structure 1. That is, a distance between the core portion 55 and the second circuit pattern structure 2 may be less than a distance between the core portion 55 and the first circuit pattern structure 1. A material of the core portion 55 may be, for example, copper (Cu), silver (Ag), gold (Au) or other high conductivity metals or alloy. The core portion 55 may be in a ball or a sphere shape. The reflowable material 56 (e.g., second solder) may include a first portion 561 (e.g., a lower portion) and a second portion 562 (e.g., an upper portion). The first portion 561 (e.g., lower portion) of the reflowable material 56 may be disposed in the openings 1445 of the fourth dielectric layer 144, and may connect the topmost circuit layer (e.g., the third circuit layer 153) of the first circuit pattern structure 1. The second portion 562 (e.g., upper portion) of the reflowable material 56 may connect the second circuit pattern structure 2. The reflowable material 56 (e.g., second solder) may electrically connect the first circuit pattern structure 1 and the second circuit pattern structure 2.

The electronic device 34 may be a semiconductor element or a semiconductor die such as an application specific integrated circuit (ASIC) die, and may be disposed above and electrically connected to the second surface 12 (e.g., top surface) of the first circuit pattern structure 1. Thus, the electronic device 34 may be disposed adjacent to or disposed over the second surface 12 (e.g., top surface) of the first circuit pattern structure 1. The electronic device 34 may be disposed between the first circuit pattern structure 1 and the second circuit pattern structure 2. The electronic device 34 has a lower surface 341 (e.g., active surface) and an upper surface 342 (e.g., back side surface) opposite to the lower surface 341 (e.g., active surface), and may include a plurality of conductive pads 345 disposed adjacent to the lower surface 341. The upper surface 342 (e.g., back side surface) of the electronic device 34 may be a top surface of the electronic structure 80 which may be opposite to the bottom surface of the electronic structure 80. A material of the conductive pad 345 may be, for example, aluminum (Al), tin (Sn), lead (Pb) or other suitable metals or alloy. In the present embodiment, the material of the conductive pad 345 is aluminum (Al). In some embodiments, the conductive pads 345 of the electronic device 34 may be bonded to the bonding pads 17 of the first circuit pattern structure 1 through a bonding material 39 such as soldering material.

The underfill 37 may be disposed in the space between the lower surface 341 (e.g., active surface) of the electronic device 34 and the second surface 12 (e.g., top surface) of the first circuit pattern structure 1 so as to cover and protect the bonding pads 17 of the first circuit pattern structure 1, the bonding material 39 and the conductive pads 345 of the electronic device 34.

The second circuit pattern structure 2 may be disposed over the top surface of the electronic structure 80. Thus, the second circuit pattern structure 2 may be located over the second surface 12 (e.g., top surface) of the first circuit pattern structure 1 and the electronic device 34. In some embodiments, the second circuit pattern structure 2 may be physically connected and electrically connected to the second surface 12 (e.g., top surface) of the first circuit pattern structure 1 through the vertical conductive structure(s) 5. The second circuit pattern structure 2 may be a redistribution structure, and may have a first surface 21 (e.g., a bottom surface), a second surface 22 (e.g., a top surface) opposite to the first surface 21, and a lateral surface 23 extending between the first surface 21 and the second surface 22. The second circuit pattern structure 2 may include a first circuit layer 24 (e.g., a topmost circuit layer), a first dielectric layer 27 (e.g., a top dielectric layer), a second circuit layer 25 (e.g., a bottommost circuit layer), a second dielectric layer 28 (e.g., a bottom dielectric layer) and at least one inner via 26. The first dielectric layer 27 (e.g., top dielectric layer) may be disposed on a top surface of the second dielectric layer 28 (e.g., a bottom dielectric layer). Alternatively, the second dielectric layer 28 may be disposed on the first dielectric layer 27. The first dielectric layer 27 and the second dielectric layer 28 may be made of a cured photoimageable dielectric (PID) material such as epoxy or polyimide (PI) including photoinitiators. In some embodiments, the second dielectric layer 28 may include solder mask.

The first circuit layer 24 (e.g., a topmost circuit layer) and the second circuit layer 25 (e.g., a bottommost circuit layer) may be embedded in the first dielectric layer 27 and the second dielectric layer 28. Each of the circuit layers 24, 25 may be a redistribution layer (RDL). In some embodiments, each of the first circuit layer 24 and the second circuit layer 25 may include a metallic layer (e.g. copper) disposed on a seed layer (e.g., titanium copper). In some embodiments, each of the first circuit layer 24 and the second circuit layer 25 may include at least one trace and at least one pad. The inner via 26 may be a monolithic inner via, and may physically connect and electrically connect the first circuit layer 24 (e.g., a topmost circuit layer) and the second circuit layer 25 (e.g., a bottommost circuit layer). In some embodiments, the second circuit pattern structure 2 may include a plurality of inner vias 26. The inner vias 26 may taper upward. That is, a width of each of the inner vias 26 may gradually decrease toward the first dielectric layer 27. In addition, the second dielectric layer 28 (e.g., bottom dielectric layer) may define a plurality of openings 284 extending through the second dielectric layer 28 to expose portions of the bottommost circuit layer (e.g., the second circuit layer 25). The second portion 562 (e.g., upper portion) of the reflowable material 56 may be disposed in the openings 284 of the second dielectric layer 28, and may connect the bottommost circuit layer (e.g., the second circuit layer 25) of the second circuit pattern structure 2.

As shown in FIG. 1, a width of the second dielectric layer 28 may be less than a width of the first dielectric layer 27 to form at least one indentation portion 29 to expose portions of the bottom surface of the first dielectric layer 27. The indentation portion 29 may be defined by two lateral surfaces 283 of the second dielectric layer 28. Alternatively, the indentation portion 29 may be disposed at the corner of the second circuit pattern structure 2. The bottom surface of the second dielectric layer 28 (e.g., the first surface 21 of the second circuit pattern structure 2) may be not a completely flat surface. The second dielectric layer 28 may be separated into a plurality of portions. Alternatively, the at least one indentation portion 29 may be defined by the first surface 21 (e.g., bottom surface) of the second circuit pattern structure 2.

The second circuit pattern structure 2 may be also referred to as “a stacked structure” or “a high-density electronic structure”, “a high-density redistribution structure” or “a high-density stacked structure.” In addition, the second circuit pattern structure 2 may be also referred to as “a first circuit pattern structure.” Each of the first circuit layer 24 and the second circuit layer 25 of the second circuit pattern structure 2 may be also referred to as “a high-density redistribution layer” or “a high-density circuit layer.” In some embodiments, a density of a circuit line (including, for example, a trace or a pad) of the high-density circuit layer (e.g., the first circuit layer 24 and the second circuit layer 25 of the second circuit pattern structure 2) is greater than a density of a circuit line of a low-density circuit layer (e.g., the circuit layers 151, 152, 153 of the first circuit pattern structure 1). That is, the count of the circuit line (including, for example, a trace or a pad) in a unit area of the high-density circuit layer is greater than the count of the circuit line in an equal unit area of the low-density circuit layer, such as about 1.2 times or greater, about 1.5 times or greater, or about 2 times or greater. Alternatively, or in combination, a line space/line width (L/S) of the high-density circuit layer is less than an L/S of the low-density circuit layer, such as about 90% or less, about 50% or less, or about 20% or less. The second circuit pattern structure 2 has a thickness T₂. The thickness T₁ of the first circuit pattern structure 1 may be greater than the thickness T₂ of the second circuit pattern structure 2.

The encapsulant 4 may be disposed on the first circuit pattern structure 1 to encapsulate the electronic device 34, the vertical conductive structure(s) 5 and the underfill 37. A material of the encapsulant 4 may be a molding compound with or without fillers. The encapsulant 4 may include a main portion 40 and a constraining portion 44 formed concurrently and integrally. The main portion 40 may be disposed in the space between the first circuit pattern structure 1 and the second circuit pattern structure 2 so as to encapsulate the electronic device 34, the vertical conductive structure(s) 5 and the underfill 37. A portion 41 of the main portion 40 may extend into the indentation portion(s) 29 of the second circuit pattern structure 2 so as to contact the first dielectric layer 27 and lateral surface(s) 283 of the second dielectric layer 28 of the second circuit pattern structure 2. Thus, the portion 41 of the main portion 40 and the indentation portion 29 may be jointed form an engagement structure 30 between the encapsulant 4 and the second circuit pattern structure 2. The engagement structure 30 may include the portion 41 of the main portion 40 and the indentation portion 29. The constraining portion 44 may include a first portion 441 and a second portion 442. The first portion 441 may cover and contact the lateral surface 13 of the first circuit pattern structure 1. The second portion 442 may cover and contact the first surface 11 (e.g., bottom surface) of the first circuit pattern structure 1. For example, the second portion 442 may cover and contact the entire first surface 11 (e.g., bottom surface) of the first circuit pattern structure 1.

The encapsulant 4 has a bottom surface 42 and a lateral surface 43 connecting to the bottom surface 42. In some embodiments, the lateral surface 43 of the encapsulant 4 may be aligned with the lateral surface 23 of the second circuit pattern structure 2, and may be misaligned with the lateral surface 13 of the first circuit pattern structure 1. The bottom surface 42 of the encapsulant 4 may be a substantially flat surface. An elevation of the bottom surface 42 of the encapsulant 4 may be lower than an elevation of the first surface 11 (e.g., bottom surface) of the first circuit pattern structure 1.

The second portion 442 of the constraining portion 44 may define at least one opening 443 in communication with the opening 1414 of the first dielectric layer 141 of the first circuit pattern structure 1 so as to accommodate a portion of the external connector 35 (e.g., first solder, solder balls or solder bumps). Thus, the electrical connector 35 may be disposed in the opening 443 of the second portion 442 of the constraining portion 44 and the opening 1414 of the first dielectric layer 141 of the first circuit pattern structure 1, and may be electrically connected to the exposed portions of the bottommost circuit layer (e.g., the first circuit layer 151) of the first circuit pattern structure 1 for external connection. The electronic package 3 may include a plurality of external connectors 35 (e.g., first solders) disposed on the bottom surface of the electronic structure 80. Thus, the encapsulant 4 may further contact at least one of the external connectors 35 (e.g., first solders) disposed adjacent to the first surface 11 (e.g., bottom surface) of the first circuit pattern structure 1. At least a portion 45 of the second portion 442 of the constraining portion 44 of the encapsulant 4 may be disposed between at least two of the external connectors 35 (e.g., first solders).

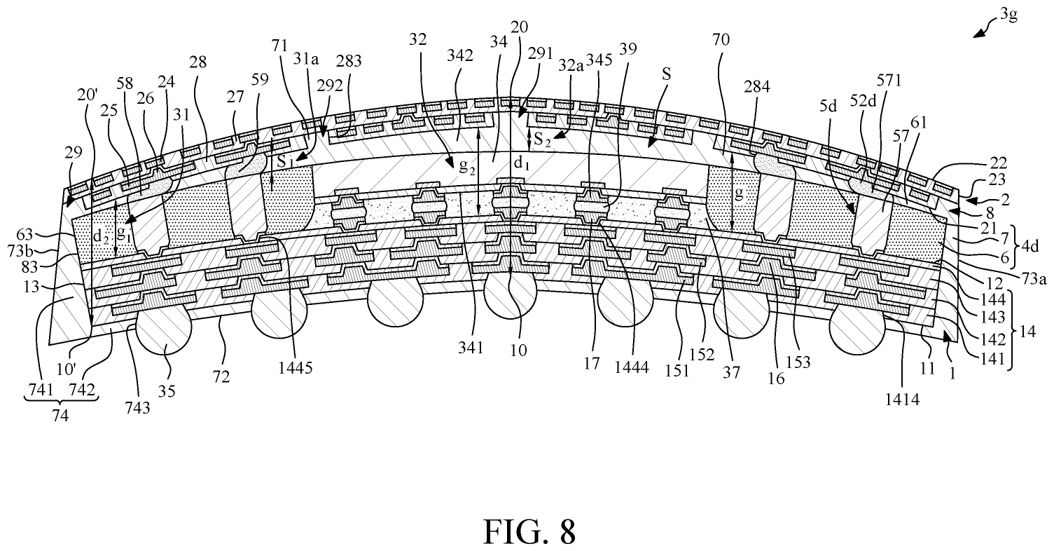

In the embodiment illustrated in FIG. 1, the first circuit pattern structure 1 may include three circuit layers 151, 152, 153. Thus, the thickness T₁ of the first circuit pattern structure 1 may be reduced, and a total thickness of the electronic package 3 may be reduced accordingly. Further, the constraining portion 44 (including the first portion 441 and the second portion 442) of the encapsulant 4 may cover and contact the lateral surface 13 of the first circuit pattern structure 1 and the first surface 11 (e.g., bottom surface) of the first circuit pattern structure 1. Thus, the rigidity of the electronic package 3 is improved, and the warpage of the first circuit pattern structure 1 is reduced. In addition, the portion 41 of the main portion 40 of the encapsulant 4 may extend into the indentation portion(s) 29 of the second circuit pattern structure 2 so as to increase the attachment and adhesion between the encapsulant 4 and the second circuit pattern structure 2, which may prevent the second circuit pattern structure 2 from peeling off from the encapsulant 4. Therefore, the yield of the electronic package 3 may be improved. In addition, the encapsulant 4 may be configured to reduce a difference between different heights of corresponding regions of a spacing S (FIG. 8) between the top surface of the electronic structure 80 and a first surface 21 (e.g., bottom surface) of the second circuit pattern structure 2. In addition, the encapsulant 4 may be configured to reduce a difference between different heights of corresponding regions of a gap g (FIG. 8) between the second surface 12 (e.g., top surface) of the first circuit pattern structure 1 and the first surface 21 (e.g., bottom surface) of the second circuit pattern structure 2.

FIG. 1A illustrates an enlarged view of an area “A” of FIG. 1. As shown in FIG. 1A, the sidewall of the opening 443 of the second portion 442 of the constraining portion 44 of the encapsulant 4 may be continuous with the sidewall of the opening 1414 of the first dielectric layer 141 of the first circuit pattern structure 1. The external connector 35 may fill the opening 443 and the opening 1414. An interface 445 between the external connector 35 (e.g., first solder) and the encapsulant 4 may include a curved surface.

FIG. 1B illustrates an enlarged view of an area of an electronic package according to some embodiments of the present disclosure. The structure of FIG. 1B is similar to the structure of FIG. 1A. As shown in FIG. 1B, the external connector 35 may not fill the opening 443 and the opening 1414. Thus, a gap G is formed between the sidewall of the opening 443 of the second portion 442 and a lateral surface 351 of the external connector 35.

FIG. 1C illustrates an enlarged view of an area of an electronic package according to some embodiments of the present disclosure. The structure of FIG. 1C is similar to the structure of FIG. 1A. As shown in FIG. 1C, the sidewall of the opening 443 of the second portion 442 of the constraining portion 44 of the encapsulant 4 may be discontinuous with the sidewall of the opening 1414 of the first dielectric layer 141 of the first circuit pattern structure 1. In addition, the external connector 35 may extend to contact a bottom surface of the second portion 442 (i.e., the bottom surface 42 of the encapsulant 4).

FIG. 1D illustrates a cross-sectional view of an electronic package 3′ according to some embodiments of the present disclosure. The electronic package 3′ of FIG. 1D is similar to the electronic package 3 of FIG. 1, and the differences are described as follows. The electronic device 34 of FIG. 1D may further include a through via 343 extending through the main body of the electronic device 34. A portion of the through via 343 may be exposed at the upper surface 342 (e.g., back side surface) of the electronic device 34, and may be electrically connected to the second circuit layer 25 of the second circuit pattern structure 2 through a solder therebetween.

As shown in FIG. 1D, the electronic package 3′ may further include an upper electronic element 36 disposed above the electronic device 34 and the second circuit pattern structure 2, and may be electrically connected to the second circuit pattern structure 2. Thus, the second circuit pattern structure 2 may be disposed between the electronic device 34 and the upper electronic element 36. The upper electronic element 36 may be a memory die or a memory chip. The electronic package 3′ may further include a first communication path 95 (e.g., an electrical path) and a second communication path 93. The first communication path 95 is from the lower surface 341 (e.g., active surface) of the electronic device 34 to the upper electronic element 36 through the first circuit pattern structure 1, the vertical conductive structure 5 and the second circuit pattern structure 2. The second communication path 93 is from the lower surface 341 (e.g., active surface) of the electronic device 34 to the upper electronic element 26 through the second circuit pattern structure 2 without passing through the first circuit pattern structure 1. Thus, the second communication path 93 is free of passing through the vertical conductive structure 5. That is, the second communication path 93 does not pass through the vertical conductive structure 5. The first communication path 95 is longer than the second communication path 93.

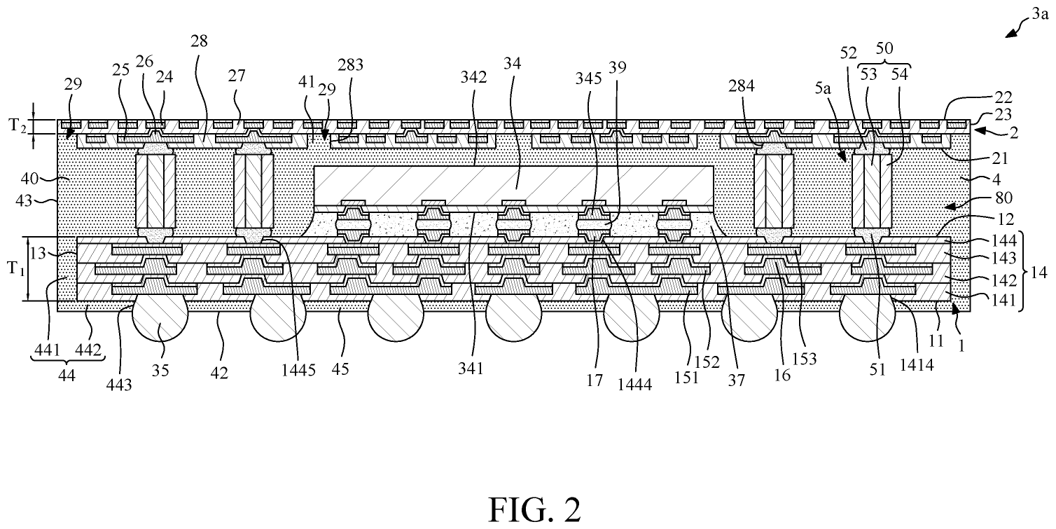

FIG. 2 illustrates a cross-sectional view of an electronic package 3a according to some embodiments of the present disclosure. The electronic package 3a of FIG. 2 is similar to the electronic package 3 of FIG. 1, except for a structure of the vertical conductive structure 5a. As shown in FIG. 2, the electronic package 3a may include a plurality of vertical conductive structures 5a spaced apart from each other. The vertical conductive structure 5a may include a pillar structure 50, a first reflowable material 51 and a second reflowable material 52. The first reflowable material 51 (e.g., solder) may be disposed in the openings 1445 of the fourth dielectric layer 144 of the first circuit pattern structure 1, and may connect a first end (e.g., bottom end) of the pillar structure 50 and the topmost circuit layer (e.g., the third circuit layer 153) of the first circuit pattern structure 1. The second reflowable material 52 may be disposed in the openings 284 of the second dielectric layer 28 of the second circuit pattern structure 2, and may connect a second end (e.g., top end) of the pillar structure 50 and the bottommost circuit layer (e.g., the second circuit layer 25) of the second circuit pattern structure 2. The pillar structure 50 may include a central conductive material 53 and a periphery insulation material 54 covering and surrounding the central conductive material 53. A material of the central conductive material 53 may be, for example, copper (Cu), silver (Ag), gold (Au) or other high conductivity metals or alloy. The central conductive material 53 may be in a cylinder shape.

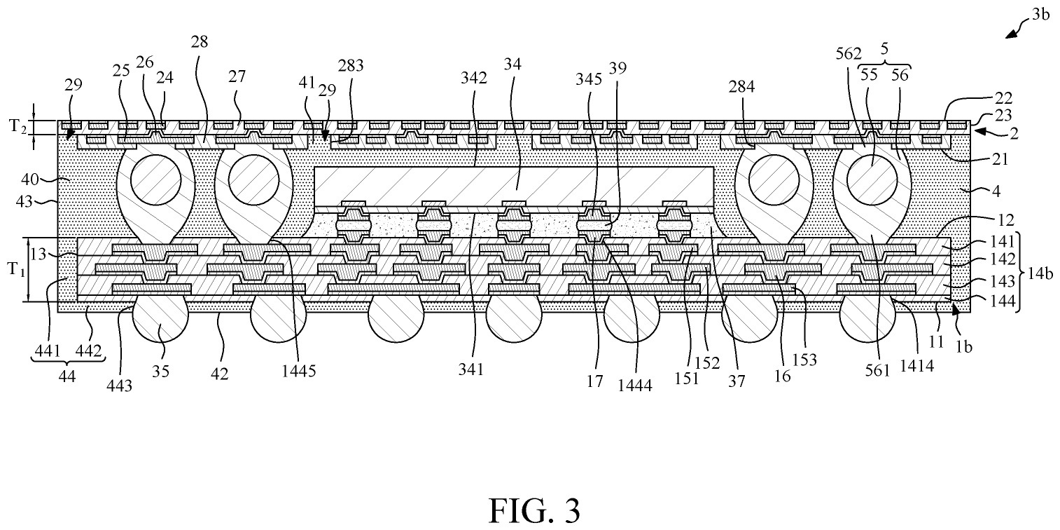

FIG. 3 illustrates a cross-sectional view of an electronic package 3b according to some embodiments of the present disclosure. The electronic package 3b of FIG. 3 is similar to the electronic package 3 of FIG. 1, except that the first circuit pattern structure 1 is upside down to become the first circuit pattern structure 1b of FIG. 3. Thus, the dielectric structure 14b of the first circuit pattern structure 1b of FIG. 3 may include the first dielectric layer 141, the second dielectric layer 142, the third dielectric layer 143 and the fourth dielectric layer 144. The first dielectric layer 141 may be the topmost dielectric layer, and the fourth dielectric layer 144 may be the bottommost dielectric layer. The inner vias 16 may taper downward.

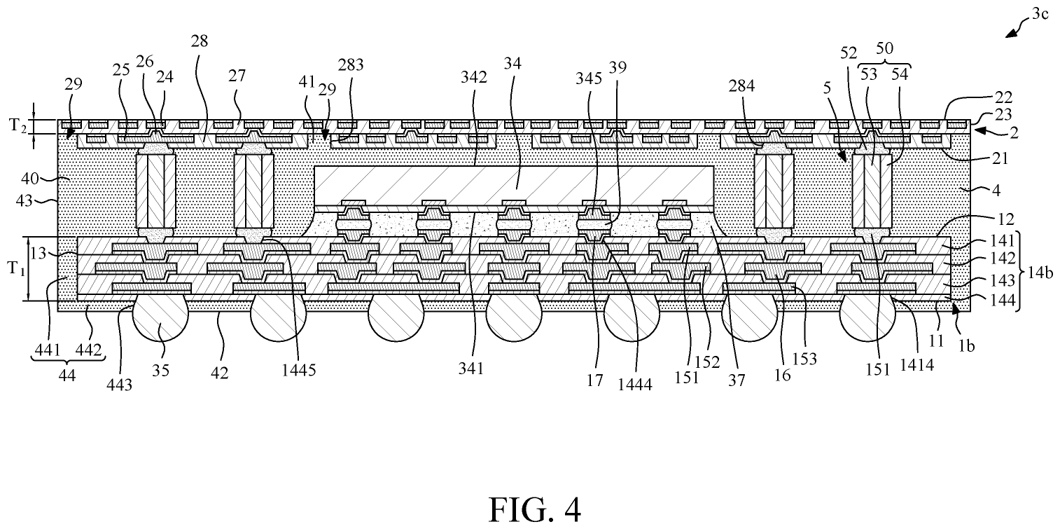

FIG. 4 illustrates a cross-sectional view of an electronic package 3c according to some embodiments of the present disclosure. The electronic package 3c of FIG. 4 is similar to the electronic package 3a of FIG. 2, except that the first circuit pattern structure 1 is upside down to become the first circuit pattern structure 1b of FIG. 4. Thus, the dielectric structure 14b of the first circuit pattern structure 1b of FIG. 4 may include the first dielectric layer 141, the second dielectric layer 142, the third dielectric layer 143 and the fourth dielectric layer 144. The first dielectric layer 141 may be the topmost dielectric layer, and the fourth dielectric layer 144 may be the bottommost dielectric layer. The inner vias 16 may taper downward.

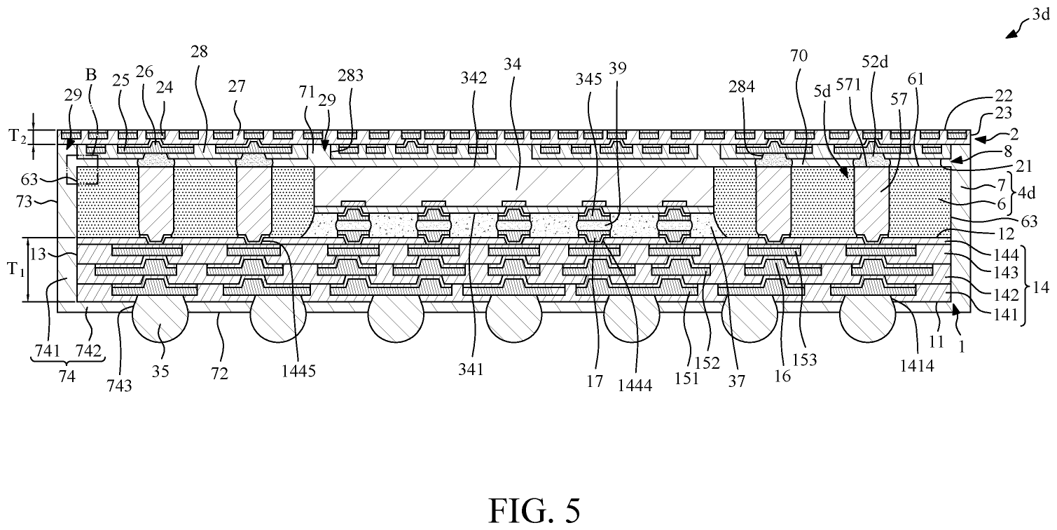

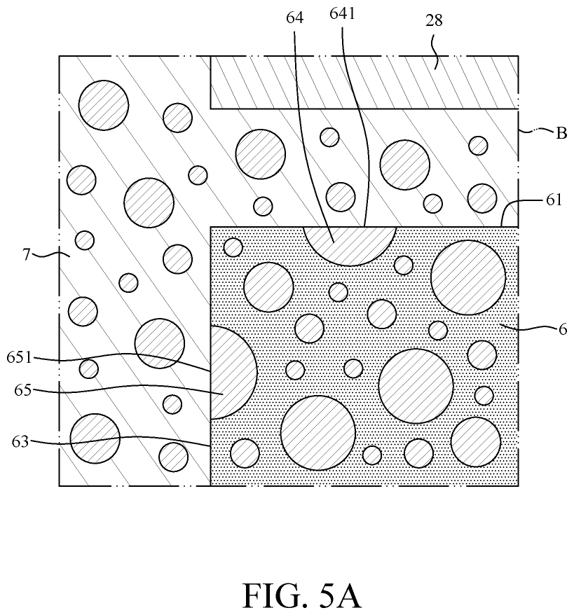

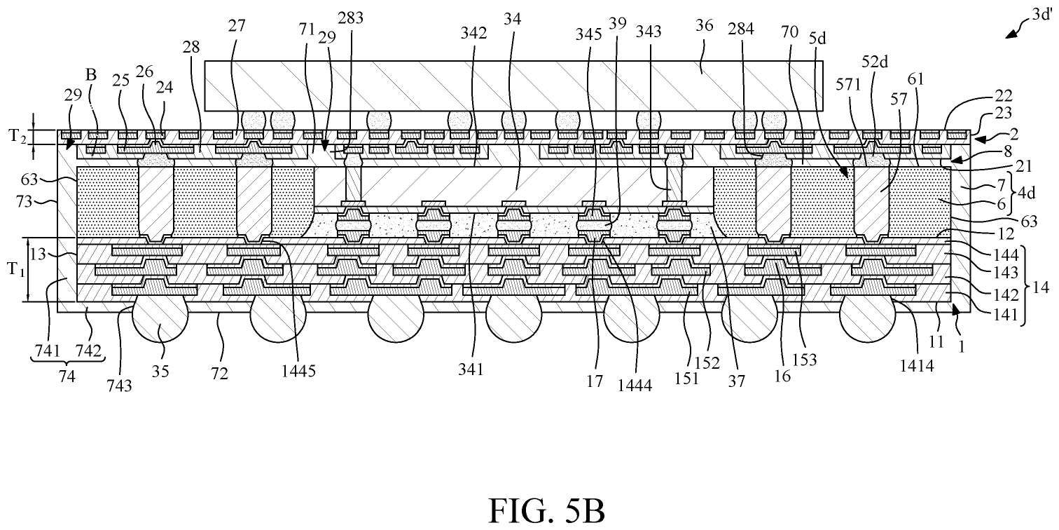

FIG. 5 illustrates a cross-sectional view of an electronic package 3d according to some embodiments of the present disclosure. The electronic package 3d of FIG. 5 is similar to the electronic package 3 of FIG. 1, and the differences are described as follows. The electronic package 3d may include an electronic structure 8 (e.g., an inner package), a second circuit pattern structure 2, a second encapsulant 7 and at least one external connector 35. The electronic structure 8 (e.g., an inner package) may include a first circuit pattern structure 1, an electronic device 34, an underfill 37, at least one conductive element 57 and a first encapsulant 6. The first circuit pattern structure 1, the electronic device 34, the underfill 37 and the second circuit pattern structure 2 of FIG. 5 may be same as the first circuit pattern structure 1, the electronic device 34, the underfill 37 and the second circuit pattern structure 2 of FIG. 1, respectively. In the electronic structure 8 (e.g., an inner package), the conductive element 57 (e.g., a pillar) may be formed on the first circuit pattern structure 1 directly. Thus, there may be no solder between the conductive element 57 and the first circuit pattern structure 1. The conductive element 57 may have a first surface 571 (e.g., a top surface) facing the second circuit pattern structure 2.

The first encapsulant 6 may be disposed on the first circuit pattern structure 1 to encapsulate the first circuit pattern structure 1, the electronic device 34, the vertical conductive structure(s) 57 and the underfill 37. A material of the first encapsulant 6 may be a molding compound with or without fillers. The first encapsulant 6 may have a first surface 61 (e.g., a top surface) and a lateral surface 63 connecting to the first surface 61 (e.g., a top surface). The first surface 61 (e.g., a top surface) of the first encapsulant 6 is the top surface of the electronic structure 8 (e.g., an inner package). The first surface 61 (e.g., a top surface) of the first encapsulant 6 may face the second circuit pattern structure 2. In some embodiments, the lateral surface 63 of the first encapsulant 6 may be substantially aligned with the lateral surface 13 of the first circuit pattern structure 1. The first surface 61 (e.g., top surface) of the first encapsulant 6 may be substantially aligned with or coplanar with the first surface 571 (e.g., a top surface) of the conductive element 57 and the upper surface 342 (e.g., back side surface) of the electronic device 34. A thickness of the first encapsulant 6 is greater than a thickness of the second circuit pattern structure 2. A thickness of the first encapsulant 6 is greater than a thickness of the first circuit pattern structure 1.

The second encapsulant 7 may encapsulate the electronic structure 8 (e.g., an inner package) (including the first circuit pattern structure 1, the electronic device 34, the underfill 37, the conductive element 57 and the first encapsulant 6). A material of the second encapsulant 7 may be a molding compound with or without fillers. The second encapsulant 7 may include a main portion 70 and a constraining portion 74 formed concurrently and integrally. The main portion 70 may be disposed in the space between the first surface 61 (e.g., a top surface) of the first encapsulant 6 of the electronic structure 8 (e.g., an inner package) and the second circuit pattern structure 2. Thus, the main portion 70 of the second encapsulant 7 may contact the first surface 61 (e.g., a top surface) of the first encapsulant 6. A portion 71 of the main portion 70 may extend into the indentation portion(s) 29 of the second circuit pattern structure 2 so as to contact the first dielectric layer 27 and lateral surface(s) 283 of the second dielectric layer 28 of the second circuit pattern structure 2.

The constraining portion 74 may include a first portion 741 and a second portion 742. The first portion 741 may cover and contact the lateral surface 13 of the first circuit pattern structure 1 and the lateral surface 63 of the first encapsulant 6. The second portion 742 may cover and contact the first surface 11 (e.g., bottom surface) of the first circuit pattern structure 1. Alternatively, the second portion 742 may be disposed on the first surface 11 (e.g., bottom surface) of the first circuit pattern structure 1. For example, the second portion 742 may cover and contact the entire first surface 11 (e.g., bottom surface) of the first circuit pattern structure 1.

The second encapsulant 7 has a bottom surface 72 and a lateral surface 73 connecting to the bottom surface 72. In some embodiments, the lateral surface 73 of the second encapsulant 7 may be aligned with the lateral surface 23 of the second circuit pattern structure 2, and may be misaligned with the lateral surface 13 of the first circuit pattern structure 1. The bottom surface 72 of the second encapsulant 7 may be a substantially flat surface. An elevation of the bottom surface 72 of the second encapsulant 7 may be lower than an elevation of the first surface 11 (e.g., bottom surface) of the first circuit pattern structure 1. The second portion 742 of the constraining portion 74 may define at least one opening 743 in communication with the opening 1414 of the first dielectric layer 141 of the first circuit pattern structure 1 so as to accommodate a portion of the external connector 35 (e.g., solder balls or solder bumps).

The electronic package 3d may further include a second reflowable material 52d. The second reflowable material 52d may be disposed in the openings 284 of the second dielectric layer 28 of the second circuit pattern structure 2, and may connect a second end (e.g., top end) of the conductive element 57 of the electronic structure 8 (e.g., an inner package) and the bottommost circuit layer (e.g., the second circuit layer 25) of the second circuit pattern structure 2. Thus, the vertical conductive structure 5d of the electronic package 3d may include the conductive element 57 of the electronic structure 8 (e.g., an inner package) and the second reflowable material 52d. The encapsulant 4d of the electronic package 3d may include the first encapsulant 6 and the second encapsulant 7.

FIG. 5A illustrates an enlarged view of an area “B” of FIG. 5. As shown in FIG. 5A, the first encapsulant 6 may include a first filler 64 and a second filler 65. The first filler 64 may have a truncated surface 641 aligned with the first surface 61 (e.g., a top surface) of the first encapsulant 6. The second filler 65 may have a truncated surface 651 aligned with the lateral surface 63 of the first encapsulant 6.

FIG. 5B illustrates a cross-sectional view of an electronic package 3d′ according to some embodiments of the present disclosure. The electronic package 3d′ of FIG. 5B is similar to the electronic package 3d of FIG. 5, and the differences are described as follows. The electronic device 34 of FIG. 5B may further include a through via 343 extending through the main body of the electronic device 34. A portion of the through via 343 may be exposed at the upper surface 342 (e.g., back side surface) of the electronic device 34, and may be electrically connected to the second circuit layer 25 of the second circuit pattern structure 2 through a solder therebetween.

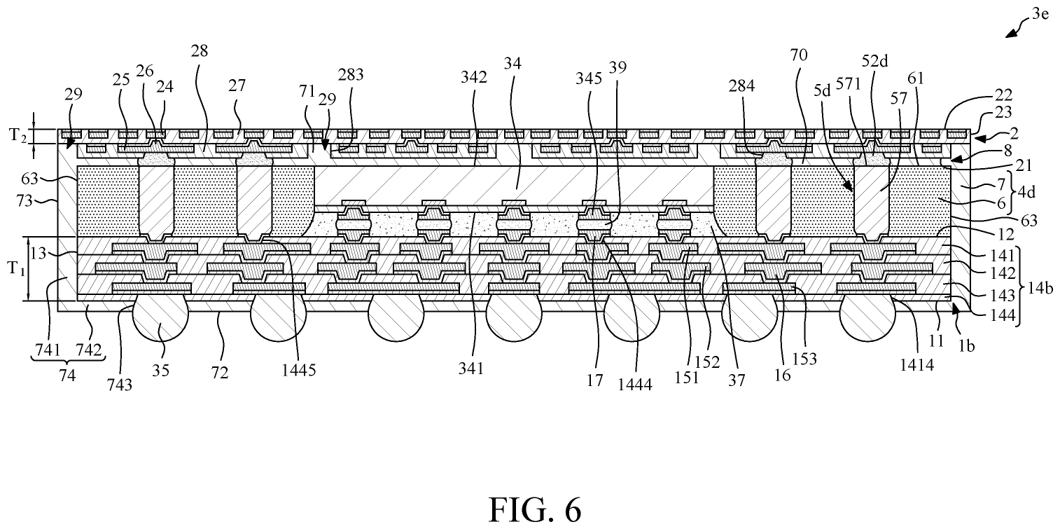

FIG. 6 illustrates a cross-sectional view of an electronic package 3e according to some embodiments of the present disclosure. The electronic package 3e of FIG. 6 is similar to the electronic package 3d of FIG. 5, except that the first circuit pattern structure 1 is upside down to become the first circuit pattern structure 1b of FIG. 6.

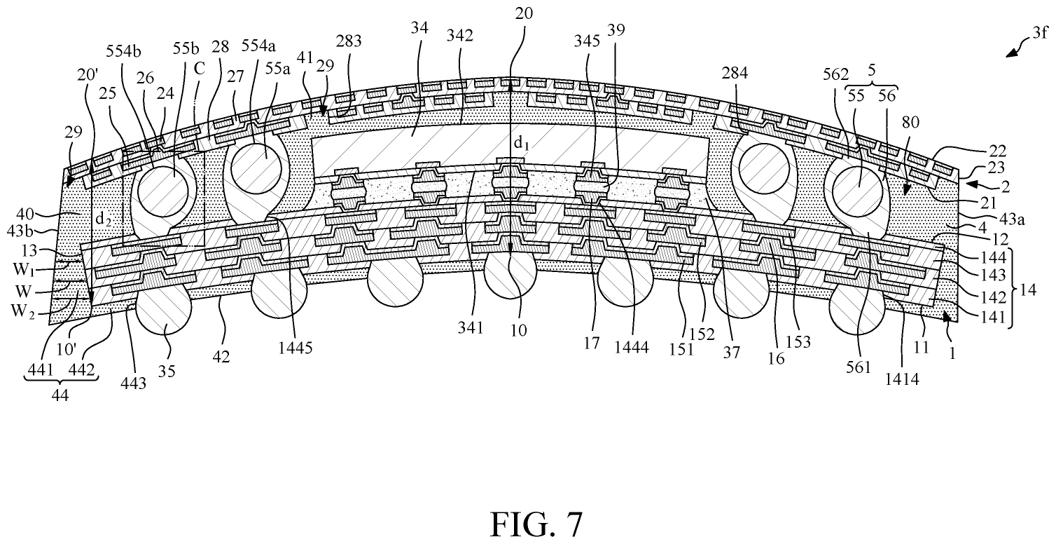

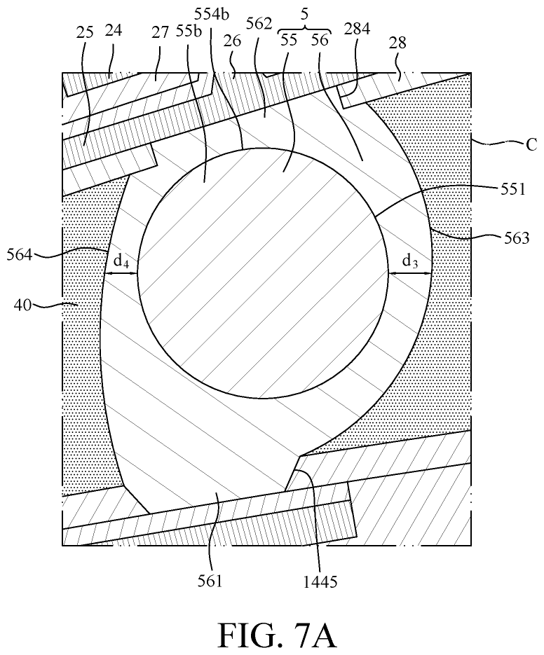

FIG. 7 illustrates a cross-sectional view of an electronic package 3f according to some embodiments of the present disclosure. The electronic package 3f of FIG. 7 is similar to the electronic package 3 of FIG. 1, except that warpage occurs. A shown in FIG. 7, a warpage of the second circuit pattern structure 2 may be greater than or severer than a warpage of the first circuit pattern structure 1. Thus, a vertical distance d₁ between a central portion 10 of the first circuit pattern structure 1 and a central portion 20 of the second circuit pattern structure 2 may be greater than a vertical distance d₂ between a periphery portion 10′ of the first circuit pattern structure 1 and a periphery portion 20′ of the second circuit pattern structure 2. The central portion 10 and the periphery portion 10′ of the first circuit pattern structure 1 may be located at the first surface 11 (e.g., bottom surface) of the first circuit pattern structure 1. The central portion 20 and the periphery portion 20′ of the second circuit pattern structure 2 may be located at the second surface 22 (e.g., a top surface) of the second circuit pattern structure 2. Thus, the vertical distance d₁ may be the distance between the first surface 11 (e.g., bottom surface) of the first circuit pattern structure 1 and the second surface 22 (e.g., a top surface) of the second circuit pattern structure 2 at the center region. The vertical distance d₂ may be the distance between the first surface 11 (e.g., bottom surface) of the first circuit pattern structure 1 and the second surface 22 (e.g., a top surface) of the second circuit pattern structure 2 at the periphery region.

In addition, the encapsulant 4 may have a first lateral surface 43a and a second lateral surface 43b. The lateral 13 of the first circuit pattern structure 1 may be nonparallel with the first lateral surface 43a and the second lateral surface 43b of the encapsulant 4. In some embodiments, a slant angle of the first lateral surface 43a may be different from a slant angle of the second lateral surface 43b. In some embodiments, the first portion 441 of the constraining portion 44 of the encapsulant 4 covering the lateral end (e.g., the lateral surface 13) of the first circuit pattern structure 1 has different thickness at different elevations between a top edge (corresponding to the second surface 12 (e.g., top surface)) of the first circuit pattern structure 1 and a bottom edge (corresponding to the first surface 11 (e.g., bottom surface)) of the first circuit pattern structure 1. That is, a thickness W of the first portion 441 of the constraining portion 44 of the encapsulant 4 varies with elevation. For example, the first portion 441 of the constraining portion 44 of the encapsulant 4 covering the lateral end (e.g., the lateral surface 13) of the first circuit pattern structure 1 has a first thickness W₁ at a higher level and a second thickness W₂ at a lower level. The second width W₂ is greater than the first width W₁. Thus, the first portion 441 of the constraining portion 44 of the encapsulant 4 may taper upward.

As shown in FIG. 7, the electronic package 3f includes a plurality of core portions 55 disposed in the plurality of reflowable materials 56 (e.g., second solders) respectively, wherein the core portions 55 are located at different elevations. The elevations of the core portions 55 increase with decreasing distance from the electronic device 34. For example, the core portions 55 may include a first core portion 55a and a second core portion 55b. The first core portion 55a is closer to the electronic device 34 than the second core portion 55b is. An elevation of a top end 554a of the first core portion 55a is higher than an elevation of a top end 554b of the second core portion 55b.

FIG. 7A illustrates an enlarged view of an area “C” of FIG. 7. As shown in FIG. 7A, the reflowable material 56 may have a first lateral surface 563 and a second lateral surface 564 opposite to the first lateral surface 563. The first lateral surface 563 may be closer to the electronic device 34 than the second lateral surface 564 is. A first distance d₃ is the distance between the lateral surface 551 of the core portion 55 and the first lateral surface 563 at an elevation. A second distance d₄ is the distance between the lateral surface 551 of the core portion 55 and the second lateral surface 564 at an elevation. The elevation of the first distance d₃ is same as the elevation of the second distance d₄. The first distance d₃ is greater than the second distance d₄. Thus, the first distance d₃ is different from the second distance d₄.

FIG. 8 illustrates a cross-sectional view of an electronic package 3g according to some embodiments of the present disclosure. The electronic package 3g of FIG. 8 is similar to the electronic package 3d of FIG. 5, except that warpage occurs. A shown in FIG. 8, a warpage of the second circuit pattern structure 2 may be greater than or severer than a warpage of the electronic structure 8 (e.g., inner package) (including the first circuit pattern structure 1). Thus, a vertical distance d₁ between a central portion 10 of the first circuit pattern structure 1 of the electronic structure 8 (e.g., inner package) and a central portion 20 of the second circuit pattern structure 2 may be greater than a vertical distance d₂ between a periphery portion 10′ of the first circuit pattern structure 1 of the electronic structure 8 (e.g., inner package) and a periphery portion 20′ of the second circuit pattern structure 2. In addition, the second encapsulant 7 may have a first lateral surface 73a and a second lateral surface 73b. The lateral 13 of the first circuit pattern structure 1 may be nonparallel with the first lateral surface 73a and the second lateral surface 73b of the second encapsulant 7. In some embodiments, a slant angle of the first lateral surface 73a may be different from a slant angle of the second lateral surface 73b.

As shown in FIG. 8, a gap g is between the second surface 12 (e.g., top surface) of the first circuit pattern structure 1 and the first surface 21 (e.g., bottom surface) of the second circuit pattern structure 2. The gap g includes a first region 31 and a second region 32. The first region 31 is closer to a lateral surface 23 of the second circuit pattern structure 2 than the second region 32 is, and a height g₁ of the first region 31 is less than a height g₂ of the second region 32.

In addition, the first surface 21 (e.g., bottom surface) of the second circuit pattern structure 2 faces the electronic structure 8 (e.g., inner package), and the first surface 21 (e.g., bottom surface) of the second circuit pattern structure 2 defines the indentation portion 29. The indentation portion 29 includes a first indentation portion 291 and a second indentation portion 292. The second indentation portion 292 is closer to a lateral end (e.g., the lateral surface 23) of the second circuit pattern structure 2 than the first indentation portion 291 is. A width of the second indentation portion 292 is less than a width of the first indentation portion 291.

As shown in FIG. 8, a spacing S may be defined as a distance or space between the first surface 21 (e.g., bottom surface) of the second circuit pattern structure 2 and the top surface of the electronic structure 8 (e.g., an inner package) (e.g., the first surface 61 (e.g., top surface) of the first encapsulant 6). The spacing S includes a third region 31a and a fourth region 32a. The third region 31a is closer to a lateral surface 83 of the electronic structure 8 (e.g., inner package) than the fourth region 32a is, and a height S₁ of the third region 31a is less than a height S₂ of the fourth region 32a.

In addition, the encapsulant (e.g., the second encapsulant 7) may be configured to reduce a difference between different heights S₁, S₂ of corresponding regions (e.g., the third region 31a and the fourth region 32a) of the spacing S between the top surface of the electronic structure 8 (e.g., the first surface 61 (e.g., top surface) of the first encapsulant 6) and the first surface 21 (e.g., bottom surface) of the second circuit pattern structure 2.

As shown in FIG. 8, the second reflowable material 52d may be an interconnection material that includes a first interconnection material 58 and a second interconnection material 59 disposed between the electronic structure 8 (e.g., inner package) and the second circuit pattern structure 2. A thickness of the first interconnection material 58 is less than a thickness of the second interconnection material 59. The first interconnection material 58 is closer to the lateral surface 83 of the electronic structure 8 (e.g., inner package) than the second interconnection material 59 is.

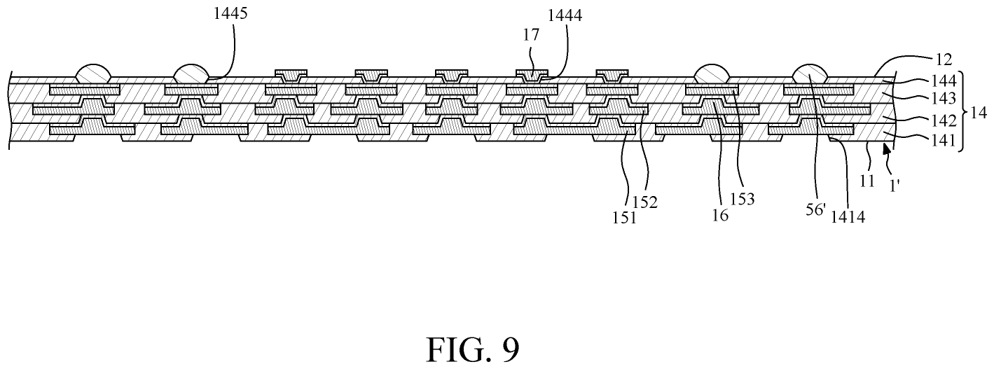

FIG. 9 through FIG. 17 illustrate a method for manufacturing an electronic package according to some embodiments of the present disclosure. In some embodiments, the method is for manufacturing the electronic package 3 shown in FIG. 1.

Referring to FIG. 9, a first circuit pattern structure 1′ is provided. The first circuit pattern structure 1′ may be in a wafer type or strip type. The first circuit pattern structure 1′ of FIG. 9 may be similar to the first circuit pattern structure 1 of FIG. 1, and may have a first surface 11 (e.g., a bottom surface) and a second surface 12 (e.g., a top surface) opposite to the first surface 11. The first circuit pattern structure 1′ may include a dielectric structure 14, a plurality of circuit layers 151, 152, 153, a plurality of inner vias 16, a plurality of bonding pads 17 and a plurality of pre-solders 56′. The dielectric structure 14 may include a plurality of dielectric layers (including, for example, a first dielectric layer 141, a second dielectric layer 142, a third dielectric layer 143 and a fourth dielectric layer 144) stacked on one another. The circuit layers 151, 152, 153 may include a first circuit layer 151, a second circuit layer 152 and a third circuit layer 153, and may be embedded in the dielectric structure 14. The inner vias 16 may electrically connect at least one of the circuit layers 151, 152, 153 or two adjacent circuit layers 151, 152, 153. The topmost dielectric layer (e.g., the fourth dielectric layer 144) may cover the topmost circuit layer (e.g., the third circuit layer 153), and may define a plurality of openings (including, for example, openings 1444 and openings 1445) to expose portions of the topmost circuit layer (e.g., the third circuit layer 153). The bonding pads 17 may be disposed in the openings 1444 of the topmost dielectric layer (e.g., the fourth dielectric layer 144) and on the exposed portions of the topmost circuit layer (e.g., the third circuit layer 153). The pre-solders 56′ may be disposed in the openings 1445 of the topmost dielectric layer (e.g., the fourth dielectric layer 144) and on the exposed portions of the topmost circuit layer (e.g., the third circuit layer 153). In addition, the first dielectric layer 141 may define a plurality of openings 1414 extending through the first dielectric layer 141 to expose portions of the bottommost circuit layer (e.g., the first circuit layer 151).

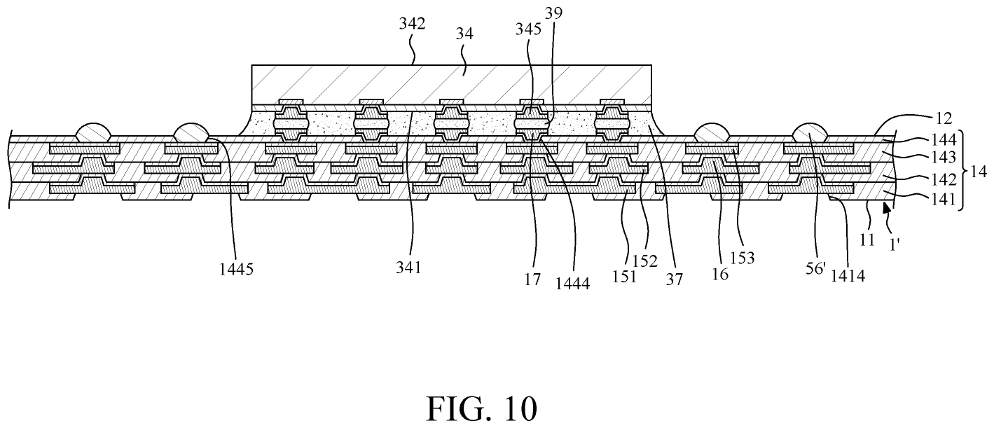

Referring to FIG. 10, an electronic device 34 may be electrically connected to the second surface 12 (e.g., top surface) of the first circuit pattern structure 1′ by flip-chip bonding. In some embodiments, the conductive pads 345 of the electronic device 34 may be bonded to the bonding pads 17 of the first circuit pattern structure 1′ through a bonding material 39 such as soldering material. Then, an underfill 37 may be applied in the space between the lower surface 341 (e.g., active surface) of the electronic device 34 and the second surface 12 (e.g., top surface) of the first circuit pattern structure 1′ so as to cover and protect the bonding pads 17 of the first circuit pattern structure 1′, the bonding material 39 and the conductive pads 345 of the electronic device 34.

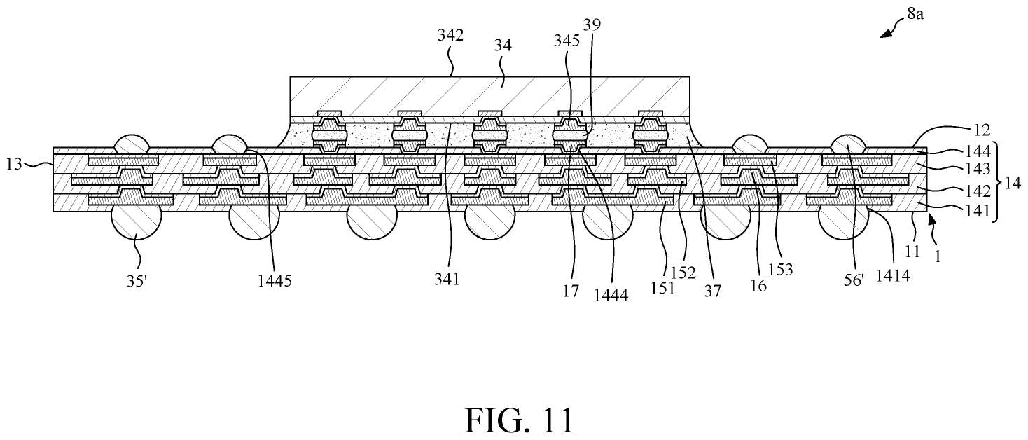

Referring to FIG. 11, a plurality of reflowable materials 35′ may be formed or disposed in the opening 1414 of the first dielectric layer 141 of the first circuit pattern structure 1′, and may be electrically connected to the exposed portions of the bottommost circuit layer (e.g., the first circuit layer 151) of the first circuit pattern structure 1′. Then, the first circuit pattern structure 1′ is singulated to form a plurality of first circuit pattern structures 1. Meanwhile, a plurality of packages 8a are obtained. The package 8a of FIG. 11 is the electronic structure 80 of FIG. 1.

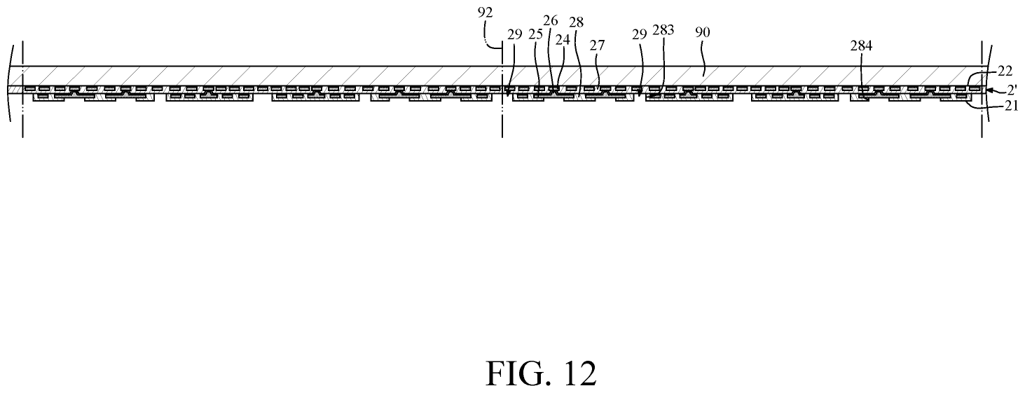

Referring to FIG. 12, a second circuit pattern structure 2′ may be formed or disposed on a carrier 90. The carrier 90 may have a plurality of cutting lines 92. The second circuit pattern structure 2′ of FIG. 12 may be similar to the second circuit pattern structure 2 of FIG. 1, and may have a first surface 21 and a second surface 22 opposite to the first surface 21. The second circuit pattern structure 2′ may include a first circuit layer 24, a first dielectric layer 27, a second circuit layer 25, a second dielectric layer 28 and at least one inner via 26. The second dielectric layer 28 may be formed or disposed on the first dielectric layer 27. The first circuit layer 24 and the second circuit layer 25 may be embedded in the first dielectric layer 27 and the second dielectric layer 28. The inner via 26 may be a monolithic inner via, and may physically connect and electrically connect the first circuit layer 24 and the second circuit layer 25. In addition, the second dielectric layer 28 may define a plurality of openings 284 extending through the second dielectric layer 28 to expose portions of the second circuit layer 25. As shown in FIG. 12, a width of the second dielectric layer 28 may be less than a width of the first dielectric layer 27 to form at least one indentation portion 29 to expose portions of the first dielectric layer 27.

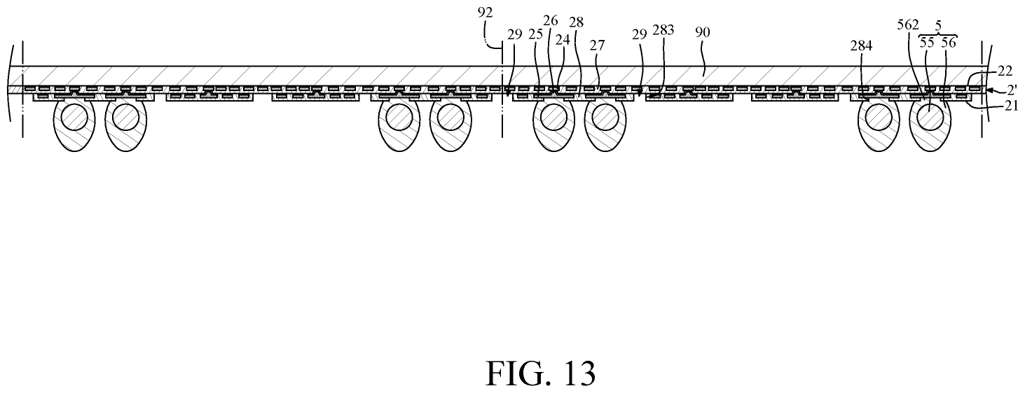

Referring to FIG. 13, a plurality of vertical conductive structures 5 may be disposed on the first surface 21 of the second circuit pattern structure 2′. The vertical conductive structure 5 may include a core portion 55 and a reflowable material 56 enclosing the core portion 55. The core portion 55 may be in a ball or a sphere shape. The reflowable material 56 (e.g., solder) may include a second portion 562 disposed in the openings 284 of the second dielectric layer 28, and may connect the second circuit layer 25 of the second circuit pattern structure 2′.

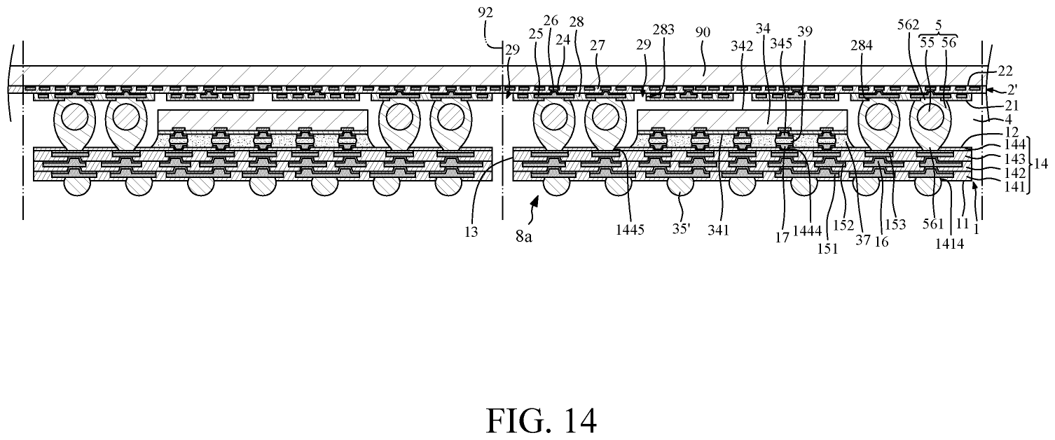

Referring to FIG. 14, the packages 8a of FIG. 11 may be attached to the second circuit pattern structure 2′ through the vertical conductive structures 5 by flip-chip bonding. Meanwhile, the pre-solders 56′ may be melted or fused into the reflowable material 56 of the vertical conductive structure 5 so as to form a first portion 561 of the reflowable material 56. The first portion 561 of the reflowable material 56 may be disposed in the openings 1445 of the fourth dielectric layer 144 of the first circuit pattern structure 1, and may connect the third circuit layer 153 of the first circuit pattern structure 1.

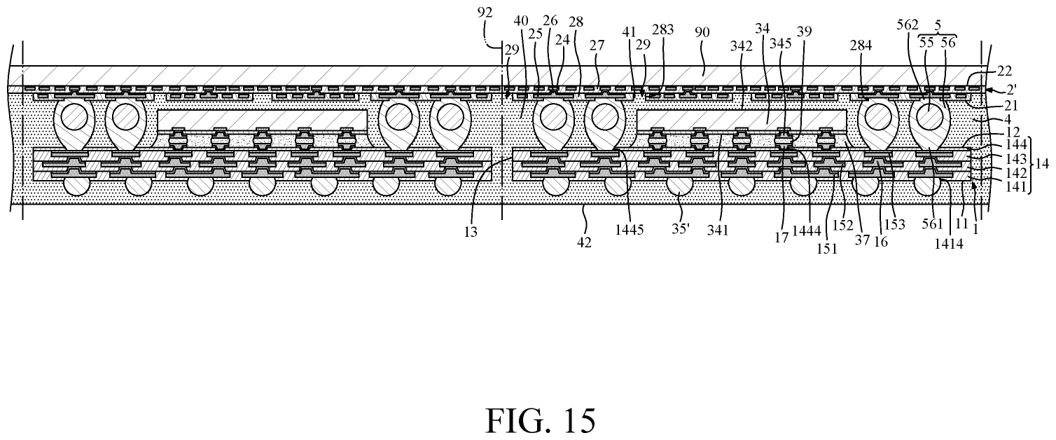

Referring to FIG. 15, an encapsulant 4 may be formed or disposed on the first surface 21 of the second circuit pattern structure 2′ to cover the vertical conductive structures 5, the packages 8a (including the first circuit pattern structure 1, the electronic device 34 and the underfill 37) and the reflowable materials 35′. A material of the encapsulant 4 may be a molding compound with or without fillers. A portion 41 of a main portion 40 of the encapsulant 4 may extend into the indentation portion(s) 29 of the second circuit pattern structure 2′ so as to contact the first dielectric layer 27 and lateral surface(s) 283 of the second dielectric layer 28 of the second circuit pattern structure 2′. The encapsulant 4 may enclose or encapsulate the entire first circuit pattern structure 1 and each of the reflowable materials 35′.

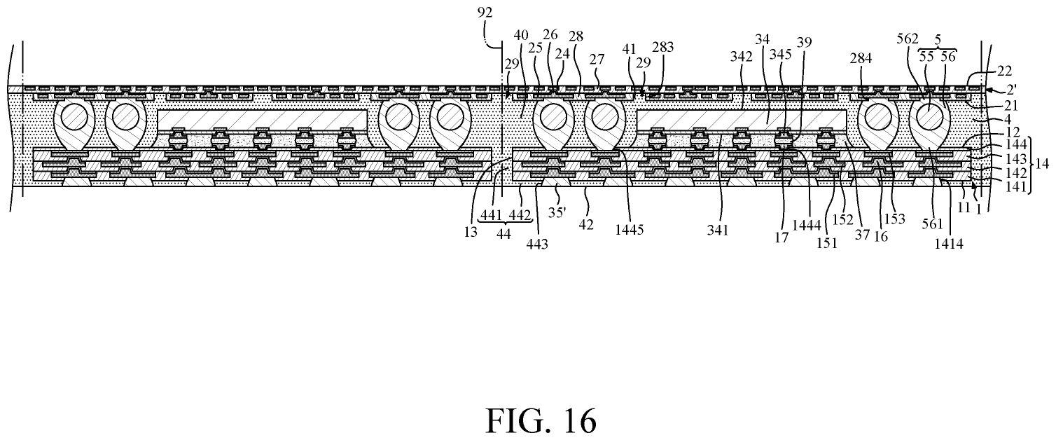

Referring to FIG. 16, the carrier 90 may be removed. Then, a grinding process may be conducted to a surface 42 of the encapsulant 4. Thus, a portion of the encapsulant 4 and a portion of each of the reflowable materials 35′ may be removed. As a result, the encapsulant 4 and the reflowable materials 35′ may be thinned, and the reflowable materials 35′ may be exposed. After the grinding process, the truncated surfaces of the reflowable materials 35′ may be aligned with or coplanar with the surface 42 of the encapsulant 4. Meanwhile, a second portion 442 of a constraining portion 44 of the encapsulant 4 may define at least one opening 443 in communication with the opening 1414 of the first dielectric layer 141 of the first circuit pattern structure 1 so as to accommodate the remaining reflowable materials 35′. It may be understood that the size and shape of the opening 443 may be determined by the reflowable materials 35′.

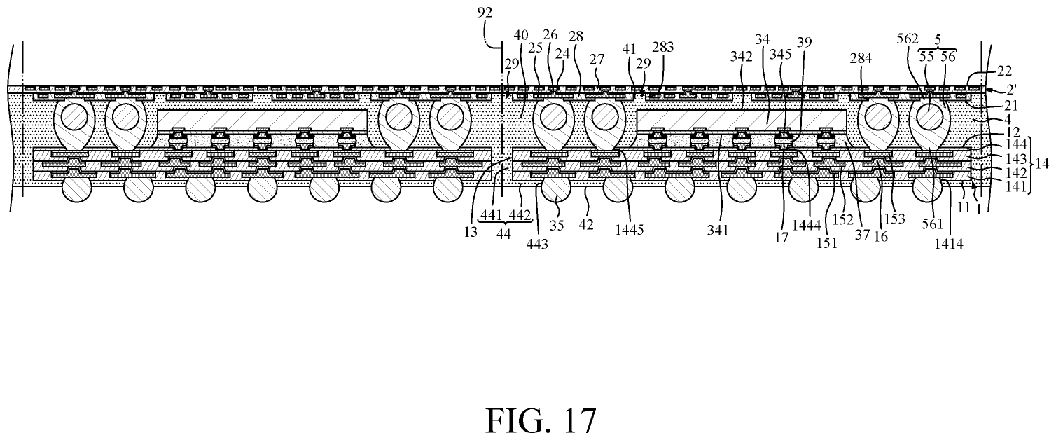

Referring to FIG. 17, a plurality of reflowable materials may be applied to the remaining reflowable materials 35′, and they may be fused or melted together to form a plurality of external connectors 35 for external connection.

Then, a singulation process may be conducted along the cutting lines 92 to obtain a plurality of electronic packages 3 of FIG. 1.

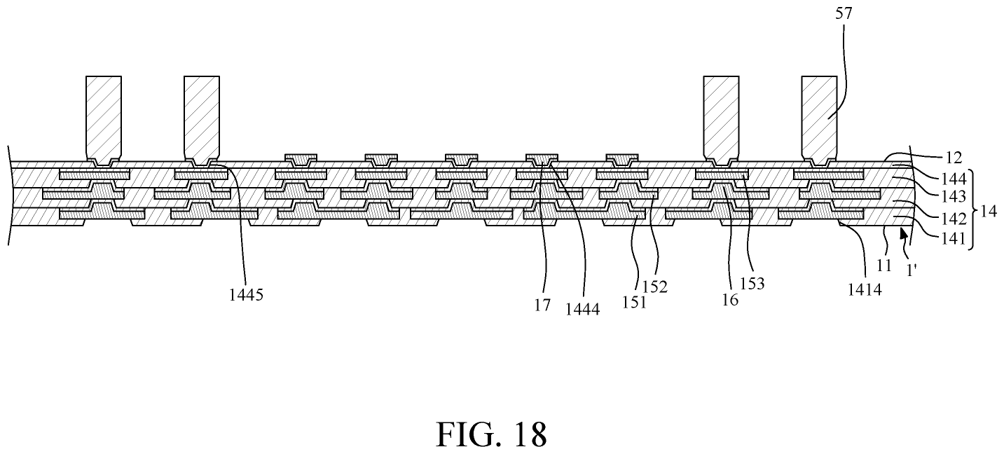

FIG. 18 through FIG. 28 illustrate a method for manufacturing an electronic package according to some embodiments of the present disclosure. In some embodiments, the method is for manufacturing the electronic package 3d shown in FIG. 5.

Referring to FIG. 18, a first circuit pattern structure 1′ is provided. The first circuit pattern structure 1′ may be in a wafer type or strip type. The first circuit pattern structure 1′ of FIG. 18 may be similar to the first circuit pattern structure 1 of FIG. 5, and may have a first surface 11 and a second surface 12 opposite to the first surface 11. The first circuit pattern structure 1′ may include a dielectric structure 14, a plurality of circuit layers 151, 152, 153, a plurality of inner vias 16 and a plurality of bonding pads 17. The dielectric structure 14 may include a plurality of dielectric layers (including, for example, a first dielectric layer 141, a second dielectric layer 142, a third dielectric layer 143 and a fourth dielectric layer 144) stacked on one another. The circuit layers 151, 152, 153 may include a first circuit layer 151, a second circuit layer 152 and a third circuit layer 153, and may be embedded in the dielectric structure 14. The inner vias 16 may electrically connect at least one of the circuit layers 151, 152, 153 or two adjacent circuit layers 151, 152, 153. The fourth dielectric layer 144) may cover the third circuit layer 153, and may define a plurality of openings (including, for example, openings 1444 and openings 1445) to expose portions of the third circuit layer 153. The bonding pads 17 may be disposed in the openings 1444 of the fourth dielectric layer 144 and on the exposed portions of the third circuit layer 153. In addition, the first dielectric layer 141 may define a plurality of openings 1414 extending through the first dielectric layer 141 to expose portions of the first circuit layer 151. Then, a plurality of conductive elements 57 (e.g., pillars) may be formed in the openings 1445 and on the first circuit pattern structure 1′.

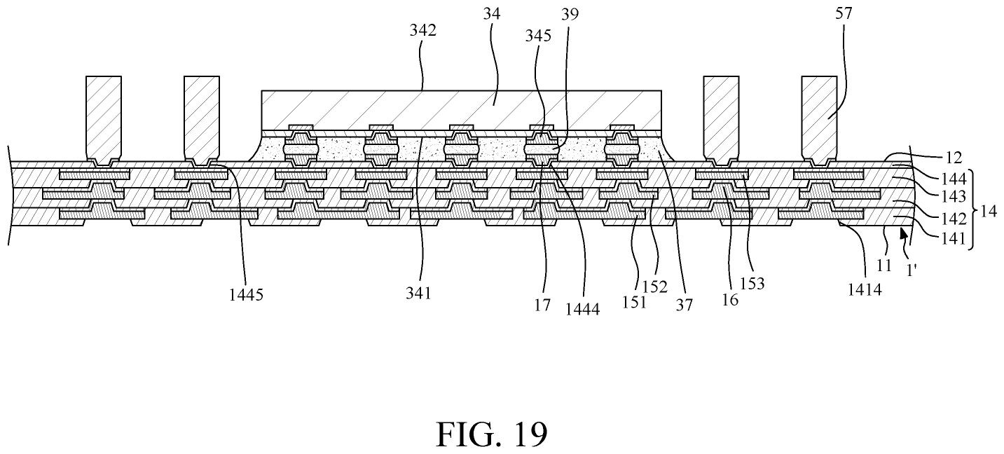

Referring to FIG. 19, an electronic device 34 may be electrically connected to the second surface 12 of the first circuit pattern structure 1′ by flip-chip bonding. In some embodiments, the conductive pads 345 of the electronic device 34 may be bonded to the bonding pads 17 of the first circuit pattern structure 1′ through a bonding material 39 such as soldering material. Then, an underfill 37 may be applied in the space between the lower surface 341 of the electronic device 34 and the second surface 12 of the first circuit pattern structure 1′ so as to cover and protect the bonding pads 17 of the first circuit pattern structure 1′, the bonding material 39 and the conductive pads 345 of the electronic device 34.

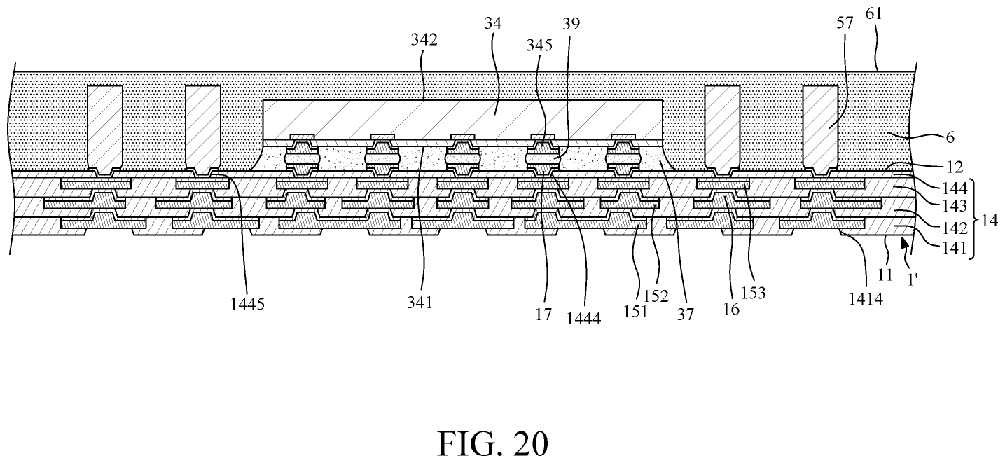

Referring to FIG. 20, a first encapsulant 6 may be formed or disposed on the second surface 12 of the first circuit pattern structure 1′ to encapsulate and cover the electronic device 34, the underfill 37 and the conductive elements 57.

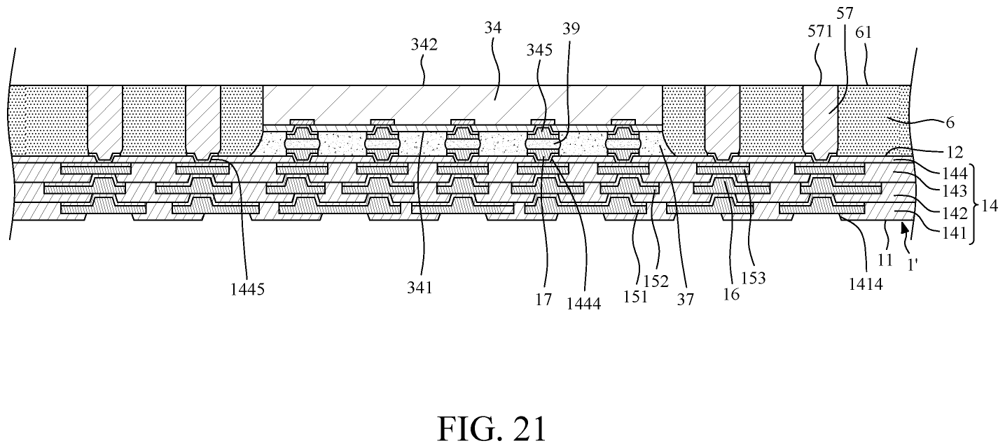

Referring to FIG. 21, the first encapsulant 6 may be thinned by, for example, grinding. Thus, the first surface 61 of the first encapsulant 6 may be substantially aligned with or coplanar with the first surfaces 571 of the conductive elements 57 and the upper surface 342 (e.g., back side surface) of the electronic device 34.

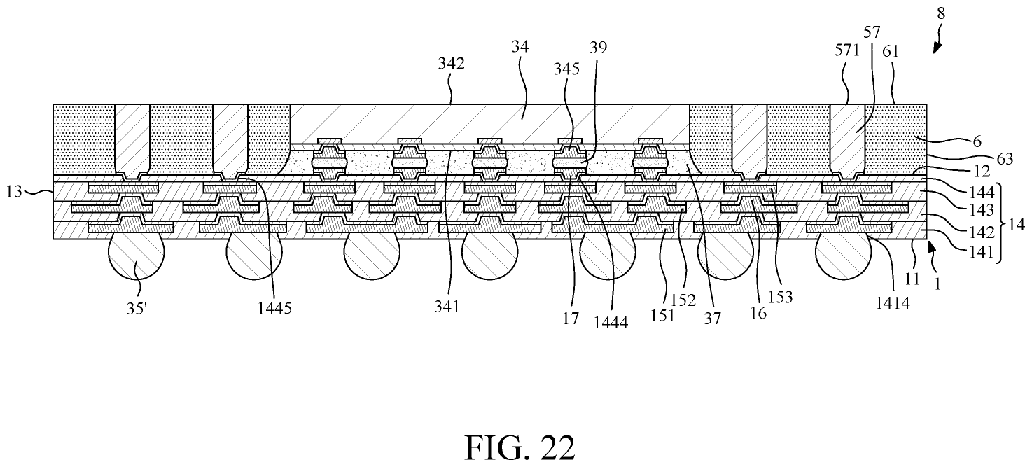

Referring to FIG. 22, a plurality of reflowable materials 35′ may be formed or disposed in the opening 1414 of the first dielectric layer 141 of the first circuit pattern structure 1′, and may be electrically connected to the exposed portions of the first circuit layer 151 of the first circuit pattern structure 1′. Then, a singulation process may be conducted to the first circuit pattern structure 1′ and the first encapsulant 6 so as to form a plurality of inner packages 8. The inner package 8 of FIG. 22 is the electronic structure 8 of FIG. 5.

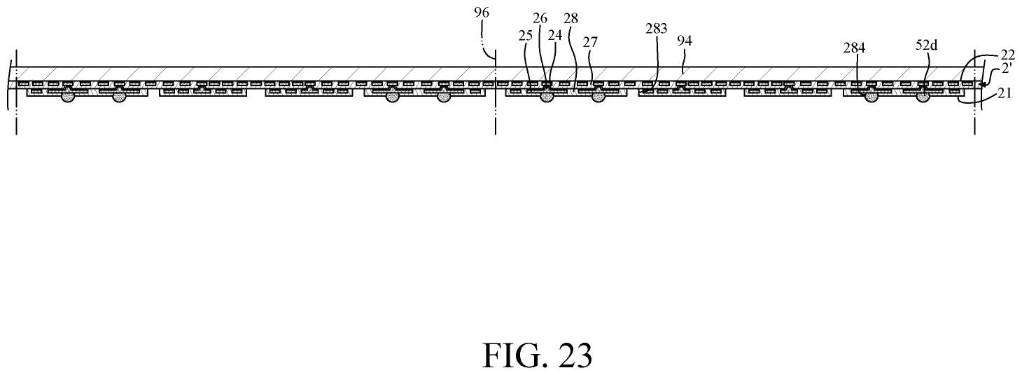

Referring to FIG. 23, a second circuit pattern structure 2′ may be formed or disposed on a carrier 94. The carrier 94 may have a plurality of cutting lines 96. The second circuit pattern structure 2′ of FIG. 23 may be similar to the second circuit pattern structure 2 of FIG. 5, and may have a first surface 21 and a second surface 22 opposite to the first surface 21. The second circuit pattern structure 2′ may include a first circuit layer 24, a first dielectric layer 27, a second circuit layer 25, a second dielectric layer 28 and at least one inner via 26. The second dielectric layer 28 may be formed or disposed on the first dielectric layer 27. The first circuit layer 24 and the second circuit layer 25 may be embedded in the first dielectric layer 27 and the second dielectric layer 28. The inner via 26 may be a monolithic inner via, and may physically connect and electrically connect the first circuit layer 24 and the second circuit layer 25. In addition, the second dielectric layer 28 may define a plurality of openings 284 extending through the second dielectric layer 28 to expose portions of the second circuit layer 25. As shown in FIG. 23, a width of the second dielectric layer 28 may be less than a width of the first dielectric layer 27 to form at least one indentation portion 29 to expose portions of the first dielectric layer 27.

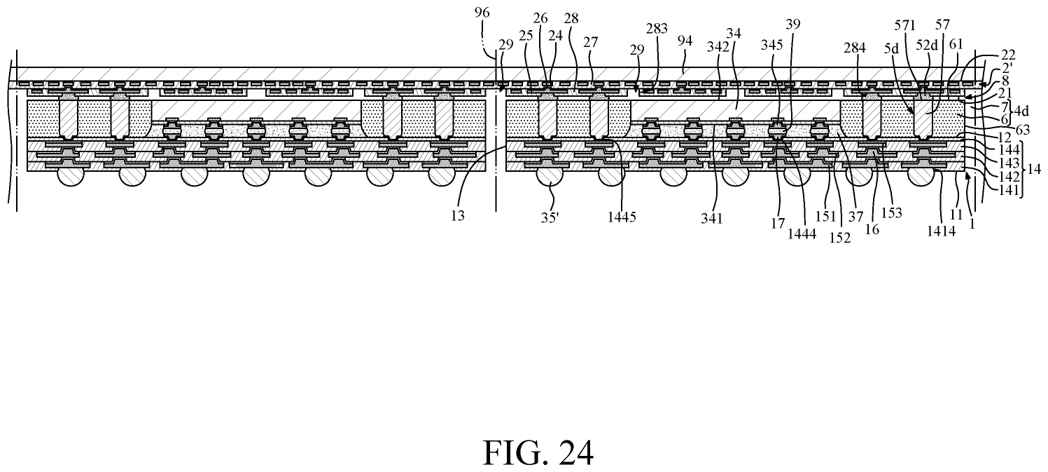

Referring to FIG. 24, the inner packages 8 of FIG. 22 may be attached to the second circuit pattern structure 2′ through the second reflowable material 52d by flip-chip bonding. Meanwhile, the second reflowable material 52d may be disposed in the opening 284 of the second dielectric layer 28, and may connect the second circuit layer 25 of the second circuit pattern structure 2′. In addition, the second reflowable material 52d may contact the first surface 571 of the conductive element 57.

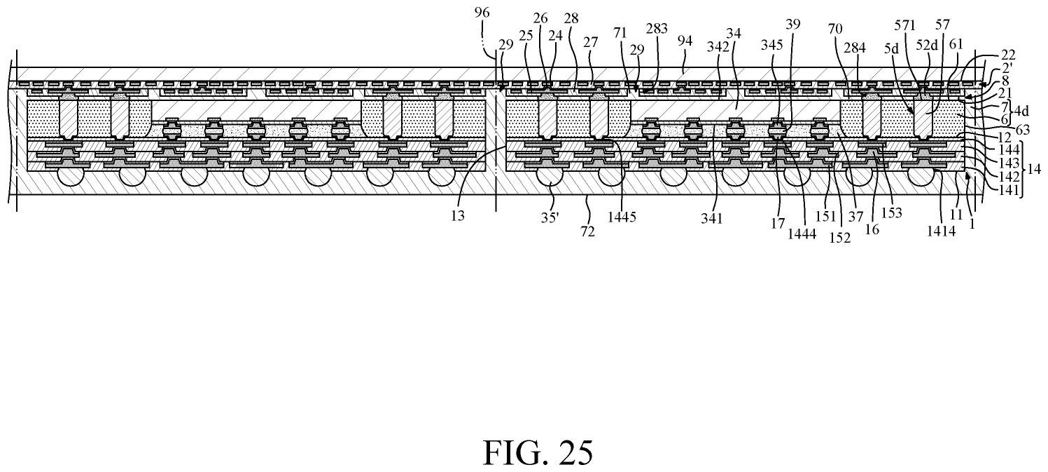

Referring to FIG. 25, a second encapsulant 7 may be formed or disposed on the first surface 21 of the second circuit pattern structure 2′ to cover the inner packages 8 and the reflowable materials 35′. A portion 71 of a main portion 70 of the second encapsulant 7 may extend into the indentation portion(s) 29 of the second circuit pattern structure 2′ so as to contact the first dielectric layer 27 and lateral surface(s) 283 of the second dielectric layer 28 of the second circuit pattern structure 2′. The second encapsulant 7 may enclose or encapsulate the entire electronic structure 8 (e.g., an inner package) and each of the reflowable materials 35′.

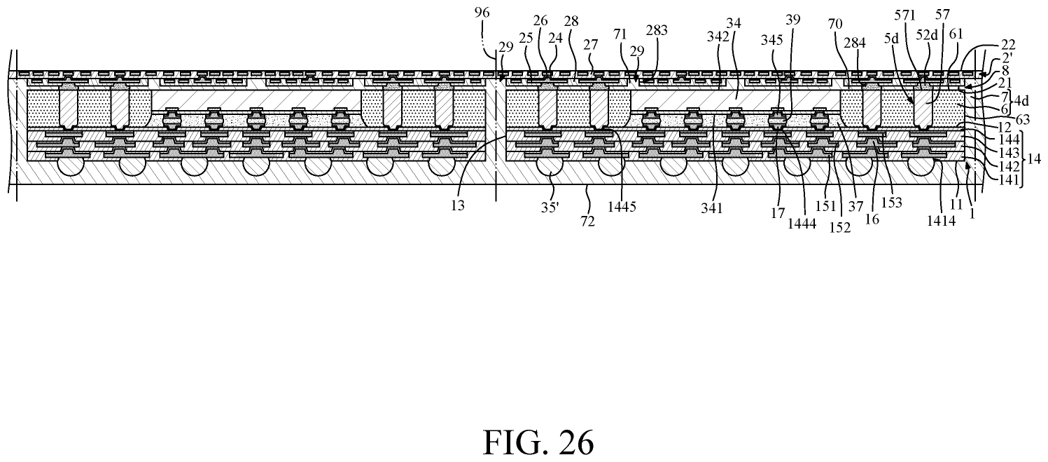

Referring to FIG. 26, the carrier 94 may be removed.

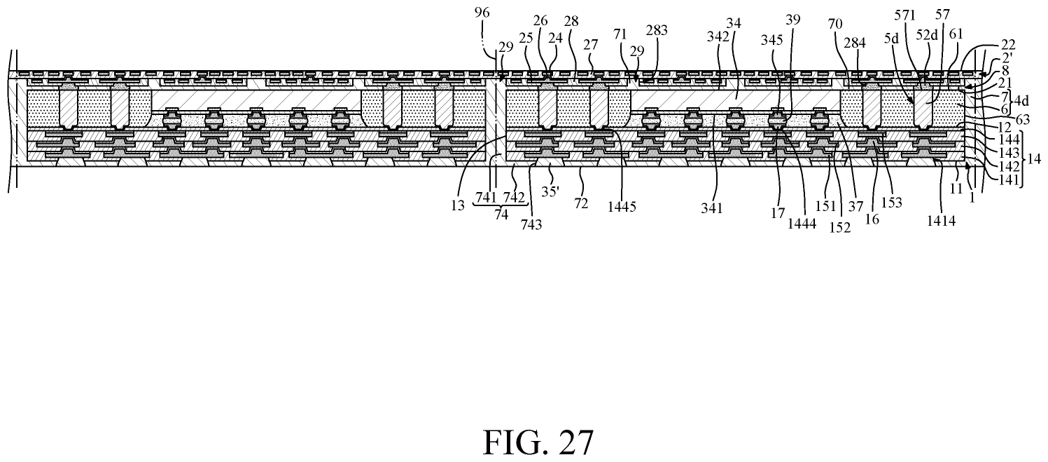

Referring to FIG. 27, a grinding process may be conducted to a surface 72 of the second encapsulant 7. Thus, a portion of the second encapsulant 7 and a portion of each of the reflowable materials 35′ may be removed. As a result, the second encapsulant 7 and the reflowable materials 35′ may be thinned, and the reflowable materials 35′ may be exposed. After the grinding process, the truncated surfaces of the reflowable materials 35′ may be aligned with or coplanar with the surface 72 of the second encapsulant 7. Meanwhile, a second portion 742 of a constraining portion 74 of the second encapsulant 7 may define at least one opening 743 in communication with the opening 1414 of the first dielectric layer 141 of the first circuit pattern structure 1 so as to accommodate the remaining reflowable materials 35′.

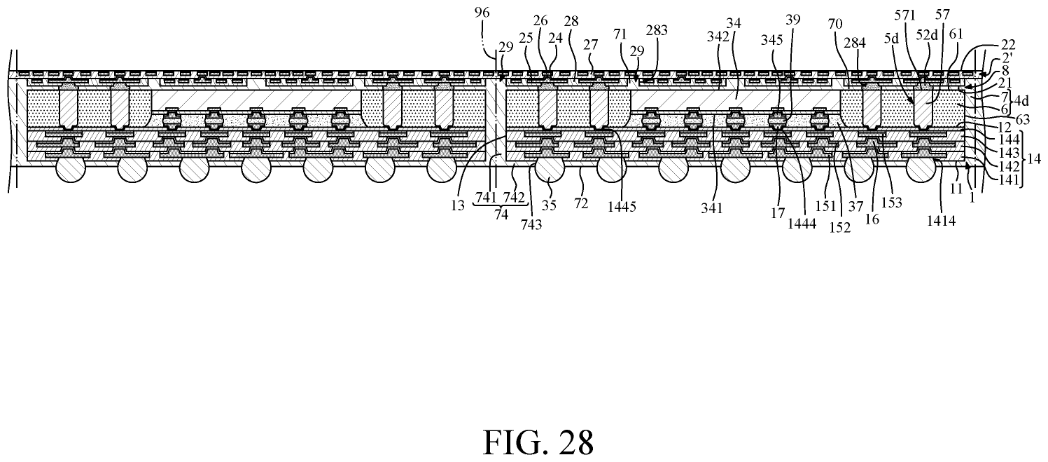

Referring to FIG. 28, a plurality of reflowable materials may be applied to the remaining reflowable materials 35′, and they may be fused or melted together to form a plurality of external connectors 35 for external connection.

Then, a singulation process may be conducted along the cutting lines 96 to obtain a plurality of electronic packages 3d of FIG. 5.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic package, comprising:
an electronic structure including an electronic device, and having a top surface and a bottom surface opposite to the top surface;
a first circuit pattern structure disposed over the top surface of the electronic structure;
a plurality of first solders disposed on the bottom surface of the electronic structure; and
an encapsulant encapsulating the electronic structure, wherein at least a portion of the encapsulant is disposed between at least two of the plurality of first solders.

2. The electronic package of claim 1, wherein the electronic structure further includes a second circuit pattern structure, the electronic device is disposed between the first circuit pattern structure and the second circuit pattern structure, a thickness of the second circuit pattern structure is greater than a thickness of the first circuit pattern structure.

3. The electronic package of claim 2, wherein at least one of the plurality of first solders contacts the encapsulant.

4. The electronic package of claim 2, wherein in a cross-sectional view, an interface between at least one of the plurality of first solders and the encapsulant includes a curved surface.

5. The electronic package of claim 1, wherein the electronic structure further includes a second circuit pattern structure, wherein in a cross-sectional view, a portion of the encapsulant covering a lateral end of the second circuit pattern structure has different thickness at different elevations between a top edge of the second circuit pattern structure and a bottom edge of the second circuit pattern structure.

6. The electronic package of claim 5, wherein the portion of the encapsulant covering the lateral end of the second circuit pattern structure has a first thickness at a higher level and a second thickness at a lower level, and the second thickness is greater than the first thickness.

7. The electronic package of claim 1, wherein the electronic structure further includes:
a second circuit pattern structure;
a second solder disposed between the first circuit pattern structure and the second circuit pattern structure; and
a core portion disposed in the second solder, wherein the core portion is closer to the first circuit pattern structure than to the second circuit pattern structure.

8. The electronic package of claim 7, wherein in a cress-sectional view, the second solder has a first lateral surface and a second lateral surface opposite to the first lateral surface, a first distance is between a lateral surface of the core portion and a first lateral surface of the second solder at an elevation, a second distance is between the lateral surface of the core portion and the second lateral surface of the second solder at the elevation, and the first distance is different from the second distance.

9. The electronic package of claim 1, wherein the electronic structure further includes:
a second circuit pattern structure;
a plurality of second solders electrically connecting the second circuit pattern structure and the first circuit pattern structure; and
a plurality of core portions disposed in the plurality of second solders respectively, wherein the plurality of core portions are located at different elevations.

10. The electronic package of claim 9, wherein the plurality of core portions include a first core portion and a second core portion, the first core portion is closer to the electronic device than the second core portion is, and an elevation of the first core portion is higher than an elevation of the second core portion.

11. An electronic package, comprising:
an electronic structure including a first circuit pattern structure; and
a second circuit pattern structure disposed over the electronic structure, wherein a gap is between the first circuit pattern structure and the second circuit pattern structure, the gap includes a first region and a second region, the first region is closer to a lateral surface of the second circuit pattern structure than the second region is, and a height of the first region is less than a height of the second region.

12. The electronic package of claim 11, further comprising:
an encapsulant encapsulating the electronic structure; and
an engagement structure between the encapsulant and the second circuit pattern structure.

13. The electronic package of claim 12, wherein the engagement structure includes at least one indentation portion defined by a bottom surface of the second circuit pattern structure and a portion of the encapsulant extending into the at least one indentation portion.

14. The electronic package of claim 13, wherein the at least one indentation portion includes a first indentation portion and a second indentation portion, the second indentation portion is closer to a lateral end of the second circuit pattern structure than the first indentation portion is, and a width of the second indentation portion is less than a width of the first indentation portion.

15. The electronic package of claim 13, wherein the second circuit pattern structure includes a redistribution layer.

16. The electronic package of claim 15, wherein a spacing is defined between a bottom surface of the second circuit pattern structure and top surface of the electronic structure, the spacing includes a third region and a fourth region, the third region is closer to a lateral surface of the electronic structure than the fourth region is, and a height of the third region is less than a height of the fourth region.

17. An electronic package, comprising:
a first circuit pattern structure;
an electronic device disposed adjacent to the first circuit pattern structure;
an upper electronic element disposed above the electronic device; and
a second circuit pattern structure disposed between the electronic device and the upper electronic element, wherein a first communication path is from the electronic device to the upper electronic element through the first circuit pattern structure, and a second communication path is from the electronic device to the upper electronic element through the second circuit pattern structure without passing through the first circuit pattern structure.

18. The electronic package of claim 17, wherein the first electrical path passes through the second circuit pattern structure.

19. The electronic package of claim 18, wherein the second circuit pattern structure is electrically connected to the first circuit pattern structure through a vertical conductive structure between the first circuit pattern structure and the second circuit pattern structure, and the first electrical path passes through the vertical conductive structure.

20. The electronic package of claim 19, wherein the second electrical path is free of passing through the vertical conductive structure.
